(19) United States
(12) Patent Application Publication
(10) Pub. No.: US 2026/0339176 A1
(43) Pub. Date: Oct. 29, 2026

(54) CAMERA MODULE AND ELECTRONIC DEVICE COMPRISING SAME

(71) Applicant: LG INNOTEK CO., LTD., Seoul (KR)

(72) Inventors: Jung Hwan BANG, Seoul (KR); Seung Hyeon JEONG, Seoul (KR)

(73) Assignee: LG INNOTEK CO., LTD., Seoul (KR)

(21) Appl. No.: 19/120,551

(22) PCT Filed: Oct. 13, 2023
(86) PCT No.: PCT/KR2023/015832

§ 371 Date: Apr. 11, 2025

(30) Foreign Application Priority Data
Oct. 13, 2022 (KR) 10-2022-0131223
Oct. 13, 2022 (KR) 10-2022-0131246

(51) Int. Cl. G03B 17/17

(52) U.S. Cl. CPC G03B 17/17

(57) ABSTRACT

A camera module, disclosed in one embodiment of the present invention, comprises: an optical member for reflecting light, and a first lens assembly for controlling the tilt of the optical member; a plurality of lens holders, and a second lens assembly for controlling the movement of at least one of the plurality of lens holders; a first substrate unit having first and second substrates disposed in first and second side parts of the first lens assembly; a second substrate unit having third and fourth substrates disposed in first and second side parts of the second lens assembly; a sensor substrate unit having an image sensor disposed; a circuit board comprising a first circuit board unit extending to the outer side of the third substrate from the sensor substrate unit; and a driver unit disposed in the inner side of the third substrate of the second substrate unit and electrically connected to the first and second substrate units and the circuit board, wherein the driver unit may be electrically connected to the first substrate unit via the first circuit board unit and the fourth substrate.

### TECHNICAL FIELD

The present invention relates to a camera module and an electronic device including the same.

### BACKGROUND ART

A camera is a device that takes pictures or videos of a subject, and is mounted on portable devices, drones, vehicles, etc. In order to improve the quality of the image, the camera module may have an Optical Image Stabilization (OIS) function that corrects or prevents image shaking caused by the user's movement, an auto-focusing (AF) function that automatically adjusts the gap between the image sensor and the lens to align the focal length of the lens, and a zooming function that increases or decreases the magnification of a distant subject through a zoom lens. However, the accuracy of posture detection for impact is deteriorating in miniaturized camera modules. In addition, there is an increasing demand for improved reliability for impact.

### DISCLOSURE

### Technical Problem

An embodiment of the invention provides a camera module having a single driver portion for controlling the optical path of a first lens assembly and a second lens assembly, and an electronic device including the same. Preferably, a camera module is provided that can be controlled by using a single driver IC required for driving a first actuator for an OIS function of a camera and a second actuator for a zoom function.

An embodiment of the invention provides a camera module having three or more channels or four channels of driver portions arranged on a second board portion in a second lens assembly for a zoom function, and electrically connected to a main board and a first board portion of the first lens assembly, and an electronic device including the same. An embodiment of the invention provides a camera module with improved zoom function and OIS function by a single driver, and an electronic device including the same.

### Technical Solution

A camera module according to an embodiment of the invention may include: a first lens assembly having an optical member that reflects incident light toward an image sensor, and a first driving portion that controls a tilt of the optical member; a plurality of lens holders arranged on a sensor side of the first lens assembly and having at least one lens; and a second lens assembly including a second driving portion that controls movement in an optical axis direction for at least one of the plurality of lens holders; a first board having a first board portion arranged on a first side of the first lens assembly and a second board arranged on a second side opposite to the first side of the first lens assembly; a second board portion having a third board arranged on a first side of the second lens assembly and a fourth board arranged on a second side of the second lens assembly; a circuit board including a sensor board portion having the image sensor arranged on an inside, and a first circuit board portion extending from the sensor board portion to an outside of the third board; and a driver portion arranged on an inside of the third board of the second board portion, and electrically connected to the first board portion, the second board portion, and the circuit board, the driver portion may be electrically connected to the first board portion through the first circuit board portion and the fourth board.

According to an embodiment of the invention, the first board portion may be arranged on a bottom of the first lens assembly, and includes a first sub-board connected to the first board and the second board, and the second board portion may be arranged on a bottom of the second lens assembly, and includes a second sub-board connected to the third board and the fourth board.

According to an embodiment of the invention, the camera module may further include a plurality of first bonding pads on an upper side of the third board and a plurality of first pads on an upper side of the first circuit board portion; a plurality of second bonding pads on a lower side of the third board and a plurality of second pads on a lower side of the first circuit board portion; a plurality of first bonding portions bonded the plurality of first bonding pads and the plurality of first pads to each other, respectively; a plurality of second bonding portions bonded the plurality of second bonding pads and the plurality of second bonding pads to each other, respectively.

According to an embodiment of the invention, the number of the first pads may be greater than the number of the second pads.

According to an embodiment of the invention, the plurality of first bonding pads, the plurality of first pads, the plurality of second bonding pads, and the plurality of second pads may be arranged in the optical axis direction.

The first circuit board portion may have a plurality of first bonding grooves on each of the plurality of first pads, and the plurality of first bonding portions may be bonded to the first bonding pad and the first pad through the plurality of first bonding grooves.

According to an embodiment of the invention, the second circuit board portion may have a plurality of second bonding grooves below each of the plurality of second pads, and the plurality of second bonding portions may be bonded to the second bonding pad and the second pad through the plurality of second bonding grooves.

According to an embodiment of the invention, the other end of the first board and one end of the first circuit board portion may have a plurality of pads and are adjacent to each other and are electrically connected by a plurality of third bonding portions, and the other end of the second board and one end of the fourth board may have a plurality of pads and are adjacent to each other and are electrically connected by a plurality of fourth bonding portions.

According to an embodiment of the invention, a plurality of third pads may be arranged in a vertical direction at one end of the first circuit board portion, and the plurality of pads arranged at the other end of the first board and the plurality of pads at one end of the fourth board may be arranged perpendicular to the optical axis direction.

According to an embodiment of the invention, the circuit board may include a connector board extending outwardly from the first circuit board portion adjacent to the driver portion.

A camera module according to an embodiment of the invention may include a first lens assembly having an optical member that reflects incident light toward an image sensor, and a first driving portion that controls a tilt of the optical member; a plurality of lens holders arranged on a sensor side of the first lens assembly and having at least one lens; and a second lens assembly including a second driving portion that controls movement in an optical axis direction for at least one of the plurality of lens holders; a first board having a first board portion arranged on a first side of the first lens assembly and a second board arranged on a second side opposite to the first side of the first lens assembly; a second board portion having a third board arranged on a first side of the second lens assembly and a fourth board arranged on a second side of the second lens assembly; a circuit board including a sensor board portion having the image sensor arranged on an inside, a first circuit board portion extending from the sensor board portion to an outside of the third board, and a second circuit board portion extending outward from the sensor board portion to an outside of the fourth board; and a driver portion arranged on an inside of the third board of the second board portion, and electrically connected to the first board portion, the second board portion, and the circuit board, the driver portion may be electrically connected to the first board portion through the circuit board.

According to an embodiment of the invention, the first board portion may be arranged on a bottom of the first lens assembly, and include a first sub-board connected to the first board and the second board, and the second board portion may be arranged on a bottom of the second lens assembly, and include a second sub-board connected to the third board and the fourth board.

According to an embodiment of the invention, the camera module may further include a plurality of first bonding pads on an upper side of the third board and a plurality of first pads on an upper side of the first circuit board portion; a plurality of second bonding pads on a lower side of the third board and a plurality of second pads on a lower side of the first circuit board portion; a plurality of first bonding portions bonded the plurality of first bonding pads and the plurality of first pads to each other, respectively; a plurality of second bonding portions bonded the plurality of second bonding pads and the plurality of second bonding pads to each other, respectively, the number of the first pads may be greater than the number of the second pads.

According to an embodiment of the invention, the plurality of first bonding pads, the plurality of first pads, the plurality of second bonding pads, and the plurality of second pads may be arranged in the optical axis direction.

According to an embodiment of the invention, the first circuit board portion may have a plurality of first bonding grooves on each of the plurality of first pads, and the plurality of first bonding portions may be bonded to the first bonding pad and the first pad through the plurality of first bonding grooves, the second circuit board portion may have a plurality of second bonding grooves below each of the plurality of second pads, and the plurality of second bonding portions may be bonded to the second bonding pad and the second pad through the plurality of second bonding grooves.

### Advantageous Effects

According to an embodiment of the invention, OIS function and zoom function of a camera module can be improved. In addition, the invention can reduce the number of driver ICs by 50%, thereby reducing the cost of modules or parts. The invention can implement a lens assembly applicable to an ultra-slim, ultra-small, and high-resolution camera. The invention can improve a reliability of an electronic device including a camera module improved a reliability and a portable terminal, an unmanned or manned moving object (a vehicle, a drone, a bike, a watercraft) having the same.

### DESCRIPTION OF DRAWINGS

FIG. 1 is an exploded perspective view of a housing and a lens assembly of a camera module according to an embodiment.

FIG. 2 is a diagram of the camera module of FIG. 1 viewed from a different direction.

FIG. 3 is an example of a combined perspective view of the camera module of FIG. 1.

FIG. 4 is an example of a combined perspective view of the camera module of FIG. 2.

FIG. 5 is a cross-sectional view of the lens assembly taken along line A-A′ of FIG. 2.

FIG. 6 is an exploded perspective view of a first lens assembly according to an embodiment.

FIG. 7 is a perspective view of a first carrier of a first lens assembly according to an embodiment.

FIG. 8 is a perspective view of the carrier of FIG. 7 viewed from a different direction.

FIG. 9 is a diagram of illustrating a first driving portion of a first lens assembly according to an embodiment.

FIG. 10 is a plan view of a driving coil and a first board portion in a first lens assembly according to an embodiment.

FIG. 11 is a cross-sectional view illustrating an example of a Y-axis tilt of the first lens assembly of FIG. 6.

FIG. 12 is a cross-sectional view illustrating an example of an X-axis and Z-axis tilt of the first lens assembly of FIG. 6.

FIG. 13 is an exploded perspective view of a second lens assembly according to an embodiment.

FIG. 14 is a detailed side cross-sectional view of the second lens assembly of FIG. 5.

FIG. 15 is an exploded perspective view of the first and second lens holders of the second assembly according to an embodiment of the invention.

FIG. 16 is an exploded perspective view of a circuit board, first and second board portions, and a lens assembly of a camera module according to the first embodiment of the invention.

FIG. 17a is a diagram viewed from one side of the camera module of FIG. 16.

FIG. 17b is a diagram viewed from the other side of the camera module of FIG. 18.

FIG. 18 is a partially enlarged diagram of the circuit board of FIG. 17a.

FIG. 19 is a diagram of illustrating a state before connection between the first circuit board portion of the circuit board of FIG. 17a and a first board of the first board portion.

FIG. 20 is a diagram of illustrating a state before connection between the second circuit board portion of the circuit board of FIG. 17a and a second board of the first board portion.

FIG. 21 is a side cross-sectional view illustrating the first and second circuit board portions of the circuit board of the second lens assembly of FIG. 17a and the third and fourth boards of the second board portion.

FIGS. 22(a)(b) is a plan view illustrating the connection between the first circuit board portion of the circuit board and the first board of the first board portion, and the connection state between the second circuit board portion and the second board in the first embodiment of the invention.

FIG. 23 is a plan view illustrating the circuit board, the first board portion, and the second board portion according to the first embodiment of the invention.

FIG. 24 is a back view of the circuit board, the first board portion, and the second board portion of FIG. 23.

FIG. 25 is a drawing illustrating the first and third bonding portions joined between the first circuit board portion of the circuit board and the first board of the first board portion in FIG. 23.

FIG. 26 is a diagram of illustrating the fourth and fifth bonding portions joined between the second circuit board portion of the circuit board and the second board of the first board portion in FIG. 23.

FIG. 27 is an example of a circuit configuration diagram electrically connecting a circuit board and a first board portion and a second board portion according to a first embodiment of the invention.

FIG. 28 is another example of a combined perspective view of the camera module of FIG. 1.

FIG. 29 is another example of a combined perspective view of the camera module of FIG. 2.

FIG. 30 is an exploded perspective view of a circuit board, first and second board portions, and a lens assembly of a camera module according to a second embodiment of the invention.

FIG. 31a is a side view of the camera module of FIG. 30.

FIG. 31b is a side view of the camera module of FIG. 32.

FIG. 32 is a partial enlarged view of the circuit board of FIG. 31a.

FIG. 33 is a diagram of illustrating an example of partial bonding between the first circuit board portion of the circuit board of FIG. 31a and the first board of the first board portion.

FIG. 34 is a diagram of illustrating an example of partial bonding between the fourth board of the second board of FIG. 31a and the second board of the first board portion.

FIG. 35 is a side cross-sectional view of the second lens assembly of FIG. 31a, illustrating the third and fourth boards of the first circuit board portion of the circuit board and the second board portion.

FIGS. 36(a)(b) are partial plan views of FIGS. 31a and 31b, illustrating an example of a connection state between the fourth board of the second board portion and the second board of the first board portion, and a connection state between the first circuit board portion of the circuit board and the first board of the first board portion.

FIG. 37 is a plan view illustrating a circuit board, a first board portion, and a second board portion according to a second embodiment of the invention.

FIG. 38 is a back view of the circuit board, the first board portion, and the second board portion of FIG. 37.

FIG. 39 is a diagram of illustrating the first and third bonding portions of the first circuit board portion and the first board of the first board portion of the circuit board in FIG. 37.

FIG. 40 is a diagram of illustrating the fourth bonding portion of the second board portion and the fourth bonding portion of the second board of the first board portion in FIG. 37.

FIG. 41 is an example of a circuit configuration diagram electrically connecting the circuit board, the first board portion, and the second board portion according to a second embodiment of the invention.

FIG. 42 is a perspective view of a mobile terminal to which a camera module is applied according to an embodiment of the invention.

FIG. 43 is a perspective view of a vehicle to which a camera module is applied according to an embodiment of the invention.

### BEST MODE

Hereinafter, preferred embodiments of the present invention will be described in detail with reference to the attached drawings. The technical idea of the present invention is not limited to some of the embodiments described, but can be implemented in various different forms, and within the scope of the technical idea of the present invention, one or more of the components among the embodiments can be selectively combined or substituted and used. In addition, terms (including technical and scientific terms) used in the embodiments of the present invention can be interpreted as meanings that can be generally understood by those skilled in the art to which the present invention belongs, unless explicitly and specifically defined and described, and terms that are commonly used, such as terms defined in a dictionary, can be interpreted in consideration of the contextual meaning of the related technology.

In addition, terms used in the embodiments of the present invention are for the purpose of describing the embodiments and are not intended to limit the present invention. In this specification, the singular may also include the plural unless specifically stated otherwise in the phrase, and when it is described as “ A and (or) at least one (or more) of B, C”, it may include one or more of all combinations that can be combined with A, B, C. In addition, when describing components of embodiments of the present invention, terms such as first, second, A, B, (a), (b), etc. may be used. These terms are only intended to distinguish the components from other components, and the nature, order, or sequence of the components are not determined by the terms. In addition, when it is described that a component is ‘connected’, ‘coupled’, or ‘connected’ to another component, it may include not only cases where the component is directly connected, coupled, or connected to the other component, but also cases where the component is ‘connected’, ‘coupled’, or ‘connected’ by another component between the component and the other component. In addition, when it is described as being formed or arranged “above or below” each component, above or below includes not only the case where two components are in direct contact with each other, but also the case where one or more other components are formed or arranged between the two components. In addition, when it is expressed as “above or below”, it may include the meaning of not only the upward direction but also the downward direction with respect to one component. In addition, the multiple embodiments described below can be combined with each other unless it is specifically stated that they cannot be combined with each other. In addition, a part omitted in the description of one embodiment among the multiple embodiments can be applied to the description of the other embodiments unless specifically stated.

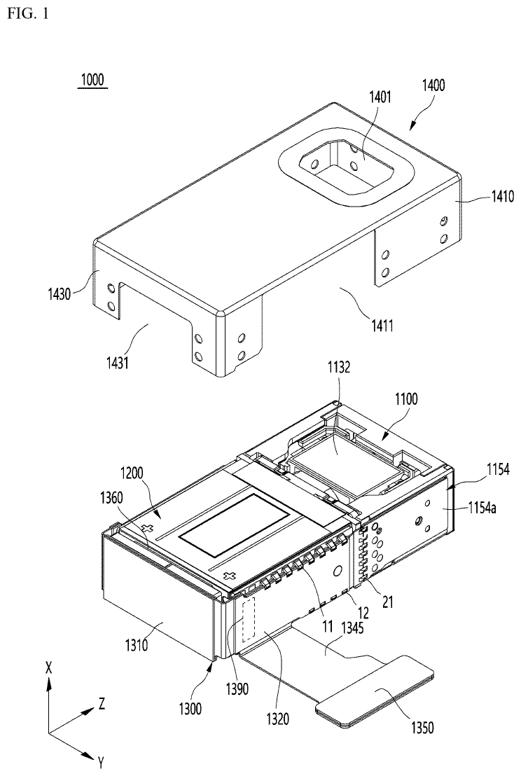

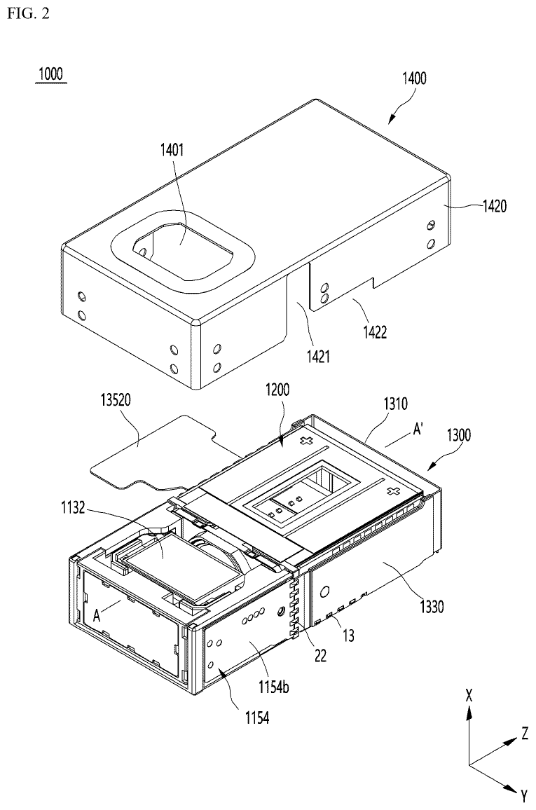

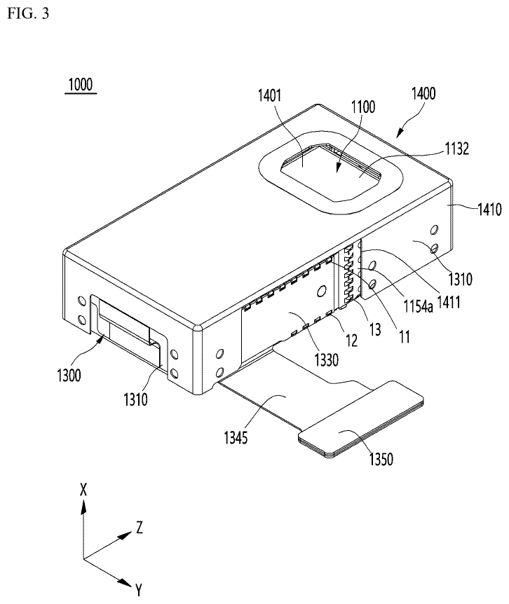

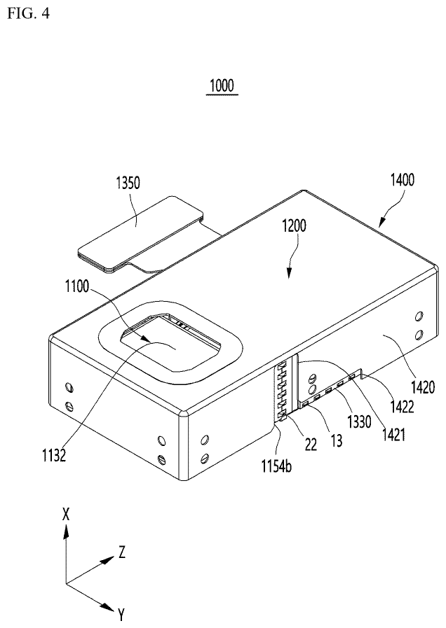

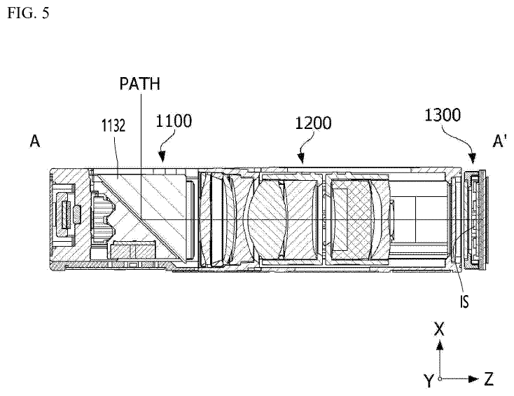

FIG. 1 is an exploded perspective view of a housing and a lens assembly of a camera module according to an embodiment, FIG. 2 is a diagram of the camera module of FIG. 1 viewed from a different direction, FIG. 3 is a combined perspective view of the camera module of FIG. 1, FIG. 4 is a combined perspective view of the camera module of FIG. 2, and FIG. 5 is a cross-sectional view taken along line A-A′ of the lens assembly of FIG. 2.

Referring to FIGS. 1 to 5, a camera module 1000 according to an embodiment may include a housing 1400, a first lens assembly 1100, a second lens assembly 1200, and a circuit board 1300. Here, the first lens assembly 1100 may be used interchangeably as a first actuator, and the second lens assembly 1200 may be used interchangeably as a second actuator.

The housing 1400 can cover the first lens assembly 1100 and the second lens assembly 1200. The bonding strength between the first lens assembly 1100 and the second lens assembly 1200 can be improved by the housing 1400. The housing 1400 can be made of a material that blocks electromagnetic waves. The housing 1400 can be made of a metal material. Accordingly, the first lens assembly 1100 and the second lens assembly 1200 within the housing 1400 can be easily protected.

The housing 1400 has a first opening 1401 that is open on an upper surface, and the first opening 1401 is an area where light is incident on the first lens assembly 1100. The first opening 1401 may overlap with the first lens assembly 1100 in the vertical direction (X). The housing 1400 has a first open region 1411 on the first side 1410, and the first open region 1411 may expose a portion of the first side of the first and second lens assemblies 1100, 1200.

The housing 1400 has second and third open regions 1421 and 1422 on the second side 1420, and the second and third open regions 1421 and 1422 may expose a portion of the second side of the first and second lens assemblies 1100, 1200.

The second and third open regions 1421 and 1422 may overlap the first open region 1411 in the horizontal direction (Y) and may be connected to each other. The sum of the areas of the second and third open regions 1421 and 1422 on each side of the housing 1400 may be smaller than the area of the first open region 1411. The housing 1400 has a fourth open region 1431 on the sensor side 1430, and a shield can (not shown) connected to the circuit board 1300 may be placed on the fourth open region 1431.

And the first lens assembly 1100 may be an Optical Image Stabilizer (OIS) actuator. For example, the first lens assembly 1100 may move an optical element in a direction perpendicular to an optical axis (axis of incident light). The first lens assembly 1100 may include a fixed focal length lens arranged in a predetermined barrel (not shown). The fixed focal length lens may be defined as a “single focal length lens” or a “single-layer lens.”

The first lens assembly 1100 may change a path of light. In an embodiment, the first lens assembly 1100 may change the path of light vertically through an optical element 1132 therein. The optical element 1132 may be, for example, a prism or a mirror. For example, the optical member 1132 can change the light from the first direction (X-axis direction) to the third direction (Z-axis direction). Or, the optical member 1132 can change the light from the first axis to the second axis. By this configuration, even if a thickness of the mobile terminal is reduced, a lens configuration larger than the thickness of the mobile terminal can be placed inside the mobile terminal through the change of the light path, so that magnification, auto-focusing (AF), zoom, and OIS functions can be performed. However, it is not limited thereto, and the first lens assembly 1100 can move the path of light in a plurality of vertical directions or tilt at a predetermined angle.

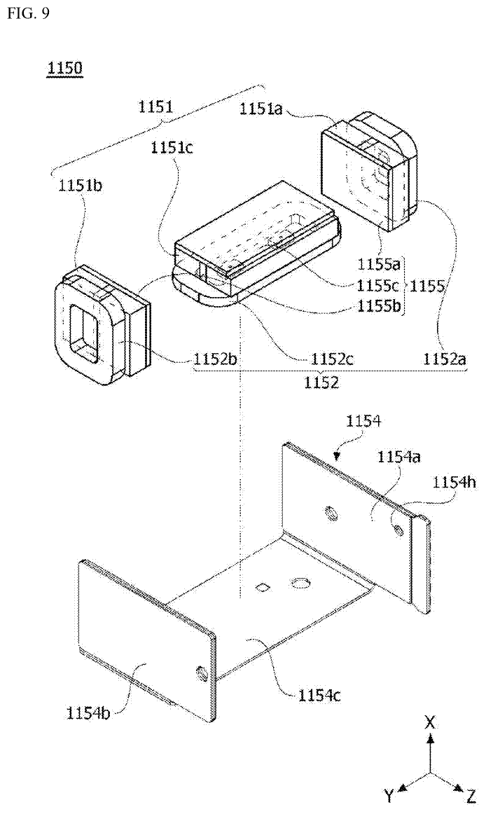

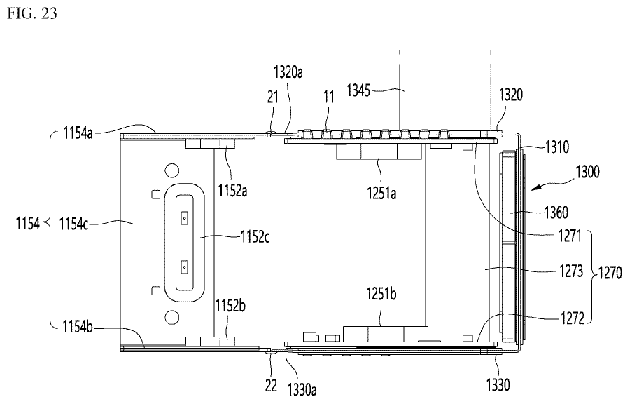

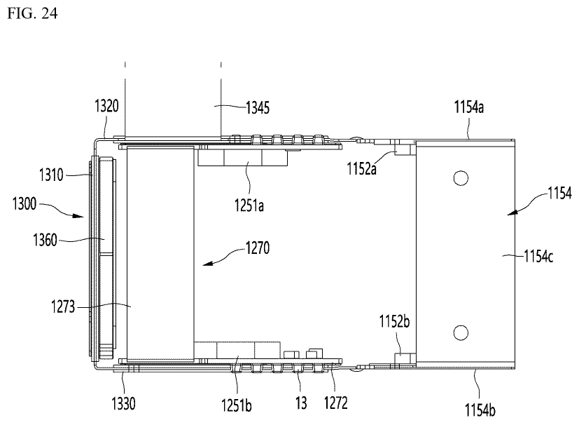

The first lens assembly 1100 may include a first board portion 1154. The first board portion 1154 may include a first board 1154a disposed on a first side or one side of the first lens assembly 1100 and a second board 1154b disposed on a second side or the other side. Each of the first board 1154a and the second board 1154b may have a multi-layer structure and may include a reinforcing plate on an outer side. The first board 1154a and the second board 1154b may be disposed on opposite sides and may be electrically connected to each other. The first board 1154a and the second board 1154b may be connected by a first sub-board 1154c, as shown in FIG. 9, FIG. 23, and FIG. 24. The first sub-board 1154c may be a flexible substrate. The first board 1154a and the second board 1154b have a rigid substrate inside and can be extended to the first sub-board 1154c.

The second lens assembly 1200 can be arranged at the rear end of the first lens assembly 1100. Here, the rear end of the first lens assembly 1100 is an area adjacent to the image sensor (IS). The second lens assembly 1200 can be arranged between the first lens assembly 1100 and the image sensor (IS), and can be coupled with the first lens assembly 1100. And the coupling therebetween can be accomplished in various ways. The second lens assembly 1200 can be a zoom actuator or an Auto Focus (AF) actuator. For example, the second lens assembly 1200 has one or more lenses and can perform an auto-focusing function or a zoom function by moving at least one lens according to a control signal of a predetermined control portion. And one or more lenses can move independently or individually along the optical axis direction.

The second lens assembly 1200 may include a second board portion 1270 on the outside, as shown in FIGS. 23 and 24. The second board portion 1270 may include a third board 1271 arranged on the first side or one side of the second lens assembly 1200 and a fourth board 1272 arranged on the second side or the other side. Each of the third board 1271 and the fourth board 1272 may have a multi-layer structure and may include a reinforcing plate on the outside. The first board 1154a and the second board 1154b may have a multi-layer structure and may include a reinforcing plate on the outside. The third board 1271 and the fourth board 1272 may be arranged on opposite sides and may be electrically connected to each other. The third board 1271 and the fourth board 1272 may be connected by a second sub-board 1273, as shown in FIGS. 23 and 24. The second sub-board 1273 may be a flexible substrate. The third board 1271 and the fourth board 1272 may have a rigid substrate inside and may extend to the second sub-board 1273.

The second board portion 1270 may include a driver portion 1390 on the inside. The driver portion 1390 supplies a signal for controlling the driving of the first and second lens assemblies 1100, 1200. The driver portion 1390 may be implemented as a chip that is a driver IC and can communicate with three or more channels, for example, four channels. The driver portion 1390 may be arranged on an inner side of the third board 1271 or the fourth board 1272, and preferably, may be arranged on the inner side of the third board 1271 adjacent to a connector board 1350. The first board portion 1154 may be provided without the driver portion, and may be provided without the driver portion, for example, on the inner side of the first or second board 1154a, 1154b. The above driver portion 1390 can communicate with two channels out of four channels to control the driving of the optical member 1132 of the first lens assembly 1100 through the first board portion 1154, and can communicate with two channels to control the driving of the lenses of the second lens assembly 1200 of the second board portion 1270.

The circuit board 1300 may be arranged at the rear end of the second lens assembly 1200. The circuit board 1300 may be electrically connected to the first and second board portions 1154, 1270 to communicate with the second lens assembly 1200 and the first lens assembly 1100. In addition, the circuit board 1300 may be a part of a sensor module 1360 having an image sensor or may be combined with the sensor module 1360. The circuit board 1300 may be arranged on the outside of the second lens assembly 1200. The circuit board 1300 may include a sensor board portion 1310 arranged at the rear of the second lens assembly 1200, a first circuit board portion 1320 arranged at the first side or one side, and a second circuit board portion 1330 arranged at the second side or the other side.

The sensor board portion 1310 has an image sensor arranged therein, and may be combined with a sensor module 1260 or may be a part of the sensor module 1260. The sensor board portion 1310, the first circuit board portion 1320, and the second circuit board portion 1330 may include a rigid substrate and may be electrically connected to each other. The curved area between the sensor board portion 1310 and the first circuit board portion 1320 may be connected to a flexible substrate. The curved area between the sensor board portion 1310 and the second circuit board portion 1330 may be connected with a flexible substrate. Each of the sensor board portion 1310, the first circuit board portion 1320, and the second circuit board portion 1330 may have a multi-layer structure and may have a reinforcing plate on the outside. The first circuit board portion 1320 and the second circuit board portion 1330 may be folded in multiple stages in opposite directions based on the sensor board portion 1310.

The sensor board portion 1310 may be arranged on the sensor side of the sensor module 1260 or the sensor side of the second lens assembly 1200. The first circuit board portion 1320 extends to the outside of the third board 1271 of the second board portion 1270 and can be electrically connected to the third board 1271 and the first board 1154a. The second circuit board portion 1330 extends to the outside of the fourth board 1272 and can be electrically connected to the fourth board 1272 and the second board 1154b.

The circuit board 1300 can include a connector board 1350. The connector board 1350 can be connected through a third sub-board 1345 extended from either the first or second circuit board portion 1320, 1330. The circuit board 1300 can be electrically connected to the outside through the connector board 1350. The connector board 1350 above is a multi-layer board, and a connector may be exposed on the upper or lower surface, and the third sub-board 1345 may be a flexible board. The circuit board 1300 may be a main board.

The first circuit board portion 1320 and the third board 1271 may be connected to each other by a plurality of first bonding portions 11 at the upper side and may be connected by a plurality of second bonding portions 12 at the lower side. The outer end of the first circuit board portion 1320 and the inner end of the first board 1154a may be connected by a plurality of third bonding portions 21. To facilitate communication, the number of the first bonding portions 11 may be greater than the number of the second bonding portions 12. The second circuit board portion 1330 and the fourth board 1272 may be connected to each other by a plurality of fourth bonding portions 13 at the bottom. One end of the second circuit board portion 1330 and the other end of the second board 1154b may be connected by a plurality of fifth bonding portions 22. Here, one end of the second circuit board portion 1330 is an area close to the object side, and the other end of the second board 1154b is an area close to the sensor side.

The plurality of first, second, and third bonding portions 11, 12, 21 may be exposed in the first open region 1411 of the housing 1400. The second open region 1421 of the housing 1400 may expose the plurality of fifth bonding portions 22, and the third open region 1422 may expose the fourth bonding portion 13. The sum of the areas of the second and third open regions 1421 and 1422 may be smaller than the sum of the areas of the first off area 1411. The first to fifth bonding portions 11, 12, 21, 13, 22 may further have a resin part (not shown) disposed on the outside for protection or sealing. The resin part (not shown) may be a resin material such as silicone or epoxy, and may protect the bonding portions from external moisture or impact.

The camera module 1000 according to the embodiment may be composed of a single or multiple camera modules. For example, the multiple camera modules may include a first camera module and a second camera module. The first camera module may include a single or multiple actuators. For example, the first camera module may include a first lens assembly 1100 and a second lens assembly 1200. In addition, the second camera module may be disposed in a predetermined housing (not shown) and may include an actuator (not shown) capable of driving the lens portion. The actuator may be a voice coil motor, a micro actuator, a silicon actuator, etc., and may be applied in various ways such as an electrostatic method, a thermal method, a bimorph method, an electrostatic force method, etc., but is not limited thereto. In addition, the first and second lens assemblies in this specification may be referred to as actuators, etc. In addition, a camera module composed of a plurality of camera modules may be mounted in various electronic devices such as a mobile terminal. In addition, the actuator may be a device that moves or tilts a lens or an optical member. However, the following description will be made with the concept that the actuator includes a lens or an optical member. Furthermore, the actuator may be referred to as a ‘lens transport device’, ‘lens transport device’, ‘optical member transport device’, or ‘optical member transport device’.

Referring to FIGS. 3, 4, and 5, the camera module according to the embodiment may include a first lens assembly 1100 having an OIS function, and a second lens assembly 1200 having a zooming function and an AF function.

Light may be incident into the camera module or the first lens assembly 1100 through a first opening 1401 located on an upper surface of the first lens assembly 1100. That is, the light may be incident into the interior of the first lens assembly 1100 along an optical axis direction (e.g., X-axis direction, based on incident light), and the optical path may be changed (e.g., changed from the X-axis direction to the Z-axis direction) through the optical member 1132. Then, the light may pass through the second lens assembly 1200 and be incident on an image sensor (IS) located at one end of the second lens assembly 1200 (PATH). In this specification, the Z-axis direction or the third direction is described as the optical axis direction as follows. In this specification, the bottom surface means one side in the first direction. And the first direction is the X-axis direction in the drawing and can be used interchangeably with the second-axis direction, etc. The second direction is the Y-axis direction in the drawing and can be used interchangeably with the first-axis direction, etc. The second direction is a direction perpendicular to the first direction. In addition, the third direction is the Z-axis direction in the drawing and can be used interchangeably with the third-axis direction, etc. And the third direction is a direction perpendicular to both the first direction and the second direction. Here, the third direction (Z-axis direction) corresponds to the direction of the optical axis, and the first direction (X-axis direction) and the second direction (Y-axis direction) are directions perpendicular to the optical axis. In addition, in the description of the second lens assembly 1200 below, the optical axis direction is the third direction (Z-axis direction), and the following description is based on this.

In addition, in the present specification, the inner side may be a direction toward the first lens assembly 1100 in the housing 1400, and the outer side may be a direction opposite to the inner side. That is, the first lens assembly 1100 and the second lens assembly 1200 may be located inside the housing 1400, and the housing 1400 may be located outside the first lens assembly 1100 or the second lens assembly 1200. The camera module 1000 according to the embodiment may improve the spatial limitations of the first lens assembly 1100 and the second lens assembly 1200 by changing the path of light. That is, the camera module 1000 according to the embodiment may expand the light path while minimizing the thickness of the camera module in response to the change in the path of light. Furthermore, it should be understood that the second lens assembly may provide a high range of magnification by controlling focus, etc. in the expanded light path. The camera module 1000 can implement OIS by controlling the optical path through the first lens assembly 1100, thereby minimizing the occurrence of decent or tilt phenomena and producing the best optical characteristics. The second lens assembly 1200 can include an optical system and a lens driving portion. For example, the second lens assembly 1200 can include one or more lens holders each having at least one lens, and for example, can include at least one of the first lens holder, the second lens holder, and the third lens holder.

The second lens assembly 1200 can perform a high-magnification zooming function and an autofocus function by having a coil and a magnet. For example, the first lens holder and the second lens holder can be moving lenses that move through a coil, a magnet, and a guide pin, and the third lens holder can be a fixed lens, but is not limited thereto. For example, the third lens holder may perform the function of a focalizer that focuses light on a specific location, and the first lens holder may perform the function of a variator that refocuses the image focused by the third lens holder, which is a condenser, on another location. Meanwhile, in the first lens holder, the distance to the subject or the image distance may change significantly, resulting in a large change in magnification, and the first lens holder, which is a variator, may play an important role in the change in the focal length or magnification of the optical system. Meanwhile, the point of view focused by the first lens holder, which is a variator, may differ slightly depending on the location. Accordingly, the second lens holder may perform the function of compensating the location of the image focused by the variator. For example, the second lens holder may perform the function of a compensator that accurately focuses the point of view focused by the first lens assembly, which is a variator, on the actual image sensor location. For example, the first lens holder and the second lens holder may be driven by an electromagnetic force resulting from the interaction of a coil and a magnet. The above-described contents can be applied to the lens holder described later. In addition, the first lens holder to the third lens holder can move along the optical axis direction, i.e., the third direction. And the first lens holder to the third lens holder can move in the third direction independently or dependently. In the present invention, the first lens holder and the second lens holder can move along the optical axis direction. And the third lens holder can be located at the front end of the first lens holder or the rear end of the second lens holder. And the third lens holder may not move in the optical axis direction. That is, the third lens holder may be a fixed part. In addition, the first and second lens holders may be movable parts.

Meanwhile, when the camera module is equipped with an actuator for OIS and an actuator for AF/Zoom, magnetic interference with the magnet for AF/Zoom can be prevented when the OIS is driven. Since the first driving magnet of the first lens assembly 1100 is arranged separately from the second lens assembly 1200, magnetic interference between the first lens assembly 1100 and the second lens assembly 1200 can be prevented. In this specification, OIS may be used interchangeably with terms such as image stabilization, optical image stabilization, optical image correction, and shake correction.

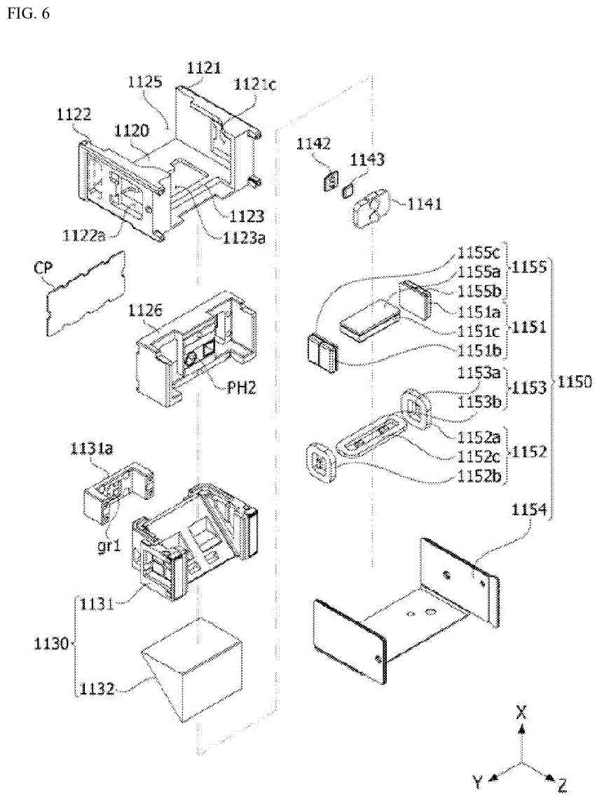

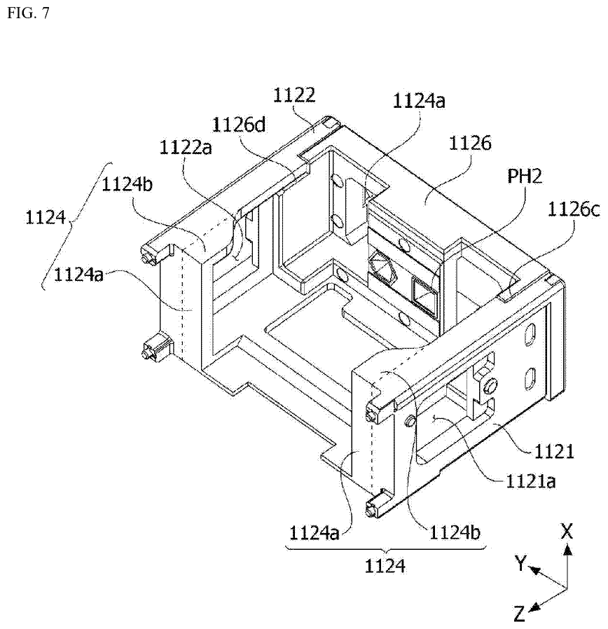

The configuration and operation of the first lens assembly will be described with reference to FIGS. 6 to 12. Referring to FIG. 6, the first lens assembly 1100 according to the embodiment may include a first carrier 1120, a mover 1130, a rotation portion 1140, a first driving portion 1150, a first member 1126, and a second member 1131a. In addition, the first lens assembly 1100 may further include a plate (CP). The mover 1130 may include a holder 1131 and an optical member 1132 mounted on the holder 1131. And the rotating portion 1140 may include a tilting guide portion 1141, a second magnetic body 1142 and a first magnetic body 1143 having the same or different polarities to press the tilting guide portion 1141. For example, the first magnetic body 1143 and the second magnetic body 1142 may have the same polarities on the surfaces facing each other. In addition, the first driving portion 1150 includes a driving magnet 1151, a driving coil 1152, a hall sensor portion 1153, a first board portion 1154, and a yoke portion 1155.

First, the first lens assembly 1100 may include a shield can (not shown). The shield can (not shown) may be positioned at the outermost side of the first lens assembly 1100 to surround the rotating portion 1140 and the first driving portion 1150 described later. The shield can (not shown) may block or reduce electromagnetic waves generated from the outside. In other words, the shield can (not shown) may reduce the occurrence of malfunctions in the first driving portion 1150.

The first carrier 1120 may be positioned inside the shield can (not shown). If there is no shield can, the first carrier 1120 may be positioned at the outermost side of the first lens assembly. In addition, the first carrier 1120 may be positioned inside the first board portion 1154 described later. The first carrier 1120 may be fitted or aligned with the shield can (not shown) and may be fastened.

As shown in FIGS. 6 to 8, the first carrier 1120 may include a first carrier side 1121, a second carrier side 1122, a third carrier side 1123, and a carrier wall 1124. A detailed description thereof will be provided later. The first member 1126 may be disposed in the first carrier 1120. The first member 1126 may have a portion penetrated by the second member 1131a. The first member 1126 may be disposed within the carrier. The first member 1126 may have a structure integral with or separate from the first carrier 1120. The first lens assembly 1100 may further include a plate (CP) disposed on the outside of the first member 1126. The plate (CP) can prevent foreign substances from entering the second member 1131a penetrating the first member 1126. In addition, the plate (CP) can be made of a magnetic material. Accordingly, the plate (CP) has magnetism and may not generate a magnetic force for the first magnetic material 1143 and the second magnetic material 1142 that have polarity for pressurization. In other words, the generation of a magnetic force that interferes with the driving (pressurization) of the first magnetic material 1143 and the second magnetic material 1142 can be reduced. If the plate (CP) is a magnetic material, it may be called a magnetic material, a magnetic material, a cover plate, a metal material, a metal plate, etc. The mover 1130 includes a holder 1131 and an optical material 1132 that is mounted on the holder 1131.

The holder 1131 can be seated in the receiving portion 1125 of the first carrier 1120. The holder 1131 can include first holder outer side surfaces to fourth holder outer side surfaces corresponding to the first carrier side surface 1121, the second carrier side surface 1122, the third carrier side surface 1123, and the first member 1126, respectively. For example, the first holder outer side surface to the fourth holder outer side surface can correspond to or face the inner side surfaces of the first carrier side surface 1121, the second carrier side surface 1122, the third carrier side surface 1123, and the first member 1126, respectively. The holder 1131 can include a second member 1131a arranged in the fourth mounting groove. The second member 1131a can penetrate the first member 1126 and be coupled with the holder 1131. The second member 1131a and the holder 1131 can be connected to each other by various joining members or bonding members. A detailed description thereof will be given later.

The optical member 1132 can be mounted on the holder 1131. To this end, the holder 1131 can have a mounting surface, and the mounting surface can be formed by a receiving groove. As an example, the optical member 1132 can be formed of a mirror or a prism. Hereinafter, a prism is illustrated as a reference, but it can also be formed of a plurality of lenses as in the above-described embodiment. Alternatively, the optical member 1132 can be formed of a plurality of lenses and a prism or a mirror. In addition, the optical member 1132 can include a reflector arranged inside. The optical member 1132 can reflect light reflected from the outside (e.g., an object) into the inside of the camera module. In other words, the optical member 1132 can improve the spatial limitation of the first lens assembly and the second lens assembly by changing the path of the reflected light. It should be understood that the camera module can provide a high range of magnification by expanding the optical path while minimizing the thickness.

Additionally, the second member 1131a can be combined with the holder 1131. The second member 1131a can be arranged on the outer side of the holder 1131 and the inner side of the carrier. And the second member 1131a can be seated in an additional groove located in an area other than the fourth mounting groove on the outer side of the fourth holder in the holder 1131. Through this, the second member 1131a can be combined with the holder 1131, and at least a part of the first member 1126 can be positioned between the second member 1131a and the holder 1131. For example, at least a part of the first member 1126 may be placed in a space formed between the second member 1131a and the holder 1131. And as described above, the second member 1131a may penetrate the hole the first through hole and the second through hole described later formed in the first member 1126. In addition, the second member 1131a may be formed as a structure separate from the holder 1131. By this configuration, as described later, the assembly of the first lens assembly may be easily performed. Alternatively, the second member 1131a may be formed integrally with the holder 1131, but will be described as a separate structure below.

The rotating portion includes a tilting guide portion 1141, a second magnetic body 1142 and a first magnetic body 1143 having the same polarity to press the tilting guide portion 1141. The tilting guide portion 1141 can be combined with the mover 1130 and the first carrier 1120 described above. Specifically, the tilting guide portion 1141 can be arranged between the holder 1131 and the first member 1126. Accordingly, the tilting guide portion 1141 can be combined with the mover 1130 of the holder 1131 and the first carrier 1120. However, unlike the above, in the present embodiment, the tilting guide portion 1141 can be arranged between the first member 1126 and the holder 1131. Specifically, the tilting guide portion 1141 can be positioned between the first member 1126 and the fourth fixing groove of the holder 1131. For example, at least a part of the tilting guide portion 1141 can be positioned in the fourth fixing groove.

As shown in FIGS. 6, 7, 8 and 11, the second member 1131a, the first member 1126, the tilting guide portion 1141 and the holder 1131 may be arranged in the order of the third direction (Z-axis direction). In addition, the second magnetic body 1142 and the first magnetic body 1143 may be respectively seated in the first groove (gr1) formed in the second member 1131a and the second groove (gr2) formed in the first member 1126. In the present embodiment, the positions of the first groove (gr1) and the second groove (gr2) may be different from the positions of the first and second grooves described in the other embodiments described above. However, the first groove (gr1) is located in the second member 1131a and moves integrally with the holder and the second member 1131a, and the second groove (gr2) is located on the first member 1126 corresponding to the first groove (gr1) and is combined with the first carrier 1120. Accordingly, the terms are used interchangeably and explained. Furthermore, the first groove and the second groove may be grooves as described above. Alternatively, the first groove and the second groove may be replaced with a hole shape.

In addition, the tilting guide portion 1141 may be arranged adjacent to the optical axis. Accordingly, the actuator according to the embodiment may easily perform a change in the optical path according to the first and second axis tilts described below. The tilting guide portion 1141 may include a first protrusion arranged spaced apart in the first direction (X-axis direction) and a second protrusion arranged spaced apart in the second direction (Y-axis direction). In addition, the first protrusion and the second protrusion may protrude in opposite directions. A detailed description thereof will be given later.

In addition, as described above, the second magnetic body 1142 may be located within the second member 1131a. In addition, the first magnetic body 1143 may be located within the first member 1126. The second magnetic body 1142 and the first magnetic body 1143 may have the same polarity. For example, the second magnetic body 1142 may be a magnet having a north pole, and the first magnetic body 1143 may be a magnet having a north pole. Or, conversely, the second magnetic body 1142 may be a magnet having a south pole, and the first magnetic body 1143 may be a magnet having a south pole. For example, as described above, the first polar surface of the first magnetic body 1143 and the second polar surface of the second magnetic body 1142 facing the first polar surface may have the same polarity.

The second magnetic body 1142 and the first magnetic body 1143 may generate a repulsive force between each other due to the polarity described above. By this configuration, the repulsive force described above is generated between the second member 1131a or holder 1131 coupled to the second magnetic body 1142 and the first magnetic body 1143 can be applied to the first member 1126 or the first carrier 1120 coupled to the second member 1131a. At this time, the repulsive force applied to the second member 1131a can be transmitted to the holder 1131 coupled with the second member 1131a. Accordingly, the tilting guide portion 1141 arranged between the second member 1131a and the first member 1126 can be pressed by the repulsive force. Furthermore, the repulsive force can be transmitted to the carrier and the mover. Accordingly, the carrier and the mover can be pressed against each other by the repulsive force. In other words, the repulsive force can correspond to the holding force that maintains the position between the carrier and the mover. That is, the repulsive force can maintain the tilting guide portion 1141 positioned between the holder 1131 and the first carrier 1120 or the first member 1126. By this configuration, the position between the mover 1130 and the first carrier 1120 can be maintained even when tilting along the X-axis or Y-axis. In addition, the tilting guide portion can be brought into close contact with the first member 1126 and the holder 1131 by the repulsive force between the first magnetic body 1143 and the second magnetic body 1142. In other words, the repulsive force by the first magnetic body 1143 and the second magnetic body 1142 can be a maintaining force for the position between the holder 1131 and the first carrier 1120.

The first driving portion 1150 includes a driving magnet 1151, a driving coil 1152, a hall sensor portion 1153, a first board portion 1154, and a yoke portion 1155. The details thereof will be described later. Additionally, the yoke portion 1155 may be referred to as the ‘first yoke portion’ in the first lens assembly. And the yoke portion in the second lens assembly may be referred to as the ‘second yoke portion.’

Referring to FIGS. 6 to 8, the first carrier 1120 according to the embodiment may include a first carrier side 1121 to a third carrier side 1123. In addition, the first member 1126 may be combined with the first carrier 1120 to form an integral part. Accordingly, the first member 1126 may be a configuration included in the first carrier 1120. Alternatively, the first carrier 1120 may include the first member 1126. The first carrier side 1121 and the second carrier side 1122 may be arranged to face each other. In addition, the first member 1216a and the carrier wall 1124 may be arranged to face each other. Furthermore, the carrier wall 1124 may be equally applied to a structure of a lens assembly in which the first member and the second member do not exist. That is, even in a structure where the mover is tilted within the carrier, the fixed carrier may include the carrier wall.

And the third carrier side 1123 may be arranged between the first carrier side 1121 and the second carrier side 1122. The third carrier side 1123 may be in contact with the first carrier side 1121 and the second carrier side 1122. And the third carrier side 1123 may be a bottom surface in the first carrier 1120. In addition, the description of the direction may be equally applied to the above-described content. And the first carrier side 1121 may include a first carrier hole 1121a. A first coil, which will be described later, may be located in the first carrier hole 1121a.

In addition, the second carrier side 1122 may include a second carrier hole 1122a. And a second coil 1152b described later may be positioned in the second carrier hole 1122a. In addition, the first carrier side 1121 and the second carrier side 1122 may be sides of the first carrier 1120. The first coil and the second coil may be coupled to the first board 1154. In an embodiment, the first coil and the second coil may be electrically connected to the first board 1154 so that current may flow. This current is a component of an electromagnetic force that allows the first lens assembly 1100 to tilt around the X-axis. In addition, the third carrier side 1123 may include a third carrier hole 1123a. The third carrier hole 1123a may be provided with a third coil 1152c to be described later. In addition, the third coil 1152c may be electrically connected to the first board portion 1154 that is in contact with the first carrier 1120 and may be coupled to each other. Accordingly, the third coil 1152c may be electrically connected to the first sub-board 1154c of the first board portion 1154 and may receive current from the first board portion 1154. This current is an element of the electromagnetic force that allows the first lens assembly 1100 to tilt around the Y-axis.

The first member 1126 may be positioned between the first carrier side portion 1121 and the third carrier side portion 1123. Accordingly, the first member 1126 may be positioned on the third carrier side portion 1123. For example, the first member 1126 may be positioned on one side. Based on the third direction, the first member 1126 and the holder may be positioned sequentially.

In addition, the first carrier 1120 may include a receiving portion 1125 formed by the first carrier side 1121 to the third carrier side 1123. The receiving portion 1125 may include the first member 1126, the second member 1131a, and the mover 1130 as components. The receiving portion 1125 may include a mover, a tilting guide portion, etc. In addition, the first carrier 1120 may further include a carrier wall portion 1124 facing the first member 1126. And the carrier wall portion 1124 is arranged between the first carrier side portion 1121 and the second carrier side portion 1122, and can be in contact with the first carrier side portion 1121, the second carrier side portion 1122, and the third carrier side portion 1123. In addition, the carrier wall portion 1124 can be located at the ends of the first carrier side portion 1121 and the second carrier side portion 1122. That is, the carrier wall portion 1124 can be plural. And the plural carrier wall portions 1124 can be located at each of the first carrier side portion 1121 and the second carrier side portion 1122. The plural carrier wall portions 1124 can be spaced apart in the second direction (Y-axis direction). Accordingly, light reflected from the optical member 1132 through the spaced region can travel to the second lens assembly 1200 at the rear end. In other words, the spaced region provides a path for the light to travel.

More specifically, the carrier wall 1124 can be arranged on a side corresponding to the emission surface of the optical member 1132. In addition, the carrier wall 1124 can be positioned between the first carrier side 1121 and the second carrier side 1122, and can be positioned at the ends of the first carrier side 1121 and the second carrier side 1122 in the optical axis direction. Accordingly, the carrier wall 1124 can be positioned at the rear end of the receiving member 1125 along the optical axis direction. Furthermore, the carrier wall 1124 can be positioned at the rear end of the optical member in the optical axis direction (Z-axis direction). And the carrier wall portion 1124 can overlap with the holder in the optical axis direction (Z-axis direction). In addition, the carrier wall portion 1124 can overlap with the holder at least partially in the optical axis direction. Here, the optical axis direction (Z-axis direction) can correspond to the movement direction of the reflected light. In addition, the optical axis direction can correspond to the vertical direction of the emission surface of the optical member. Accordingly, for the anti-shake function, even if the mover, i.e., the holder, is tilted, the movement amount can be limited by the carrier wall portion 1124. Furthermore, the carrier wall portion 1124 and the holder may collide with each other so that an impact does not occur in the first member or the second member. Thus, the reliability of the first member and the second member can be improved.

And the carrier wall portion 1124 can be formed integrally with the first carrier 1120. In addition, the carrier wall portion 1124 can be partially formed of an elastic material. In addition, an elastic member may be additionally arranged on the carrier wall portion 1124. Accordingly, the impact applied to the holder 1131 due to the collision between the carrier wall portion 1124 and the holder 1131 may be reduced.

In addition, the carrier wall portion 1124 according to the embodiment may include a wall portion 1124a facing (or corresponding to) the back surface (or the exit surface of the optical member) of the holder, and a carrier extension portion 1124b extending from the wall portion 1124a to the upper portion of the holder. The wall portion 1124a may overlap with the holder in the optical axis direction (Z-axis direction). And the carrier extension portion 1124b may overlap with the holder in the first direction. The wall portion 1124a may serve as a stopper for tilting of the holder in the first direction or the second direction. That is, when the holder is tilted, the holder and the wall 1124a may collide or come into contact with each other. And when the holder moves in the first direction or tilts in the second axis (e.g., up and down), the carrier extension 1124b may collide or come into contact with the holder. That is, the carrier extension 1124b may act as a stopper for the holder moving in the first direction. Furthermore, the third carrier side 1123 may also perform a stopper function.

In addition, as described above, the first member 1126 may be combined with the first carrier 1120 and may be a configuration included in the first carrier 1120. For example, the first member 1126 may be a structure integral with or separate from the first carrier 1120. Hereinafter, the first member 1126 will be described as a structure separated from the first carrier 1120. And the first member 1126 can be placed on the first carrier 1120. Or, the first member 1126 can be located within the first carrier 1120. And the first member 1126 can be coupled with the first carrier 1120. In an embodiment, the first member 1126 can be located between the first carrier side 1121 and the second carrier side 1122. And the first member 1126 is located on the third carrier side 1123 and can be joined to the first carrier side to the third carrier side. In addition, a stop member can be located on the inner surface of the first and second carrier sides 1121, 1122. The stop member can be positioned symmetrically with respect to the first direction (X-axis direction). By this configuration, even if the first member 1126 moves into the first carrier 1120, the position can be maintained by the stop member. The first member 1126 can be assembled or inserted laterally with respect to the first carrier 1120 and coupled with the first carrier 1120. Furthermore, the holder can be assembled along the first direction with respect to the first carrier 1120. And as described above, the first member 1126 can be coupled to the first carrier 1120 laterally, that is, along the optical axis direction. And the second member can be assembled or inserted along the optical axis direction. Thus, the second member can penetrate the first member 1126. Afterwards, the plate can be additionally placed on the first member 1126.

In addition, the first member 1126 includes a second protrusion groove (PH2) on which the second protrusion of the tilting guide portion is seated. The second protrusion groove (PH2) may be located on the inner surface 1126s1 of the first member 1126. The second protrusion groove (PH2) may be applied in the same manner as described for the first protrusion groove, as described later. For example, the number of second protrusion grooves (PH2) may be plural, and may have a structure having the same or different contact points as the second protrusion of the tilting guide portion. For example, the number of second protrusion grooves (PH2) may be 2, and may have 4-point and 8-point contact structures. That is, the second protrusion groove (PH2) may be formed of a plurality of inclined surfaces. In addition, the second protrusion groove (PH2) may be a hemispherical groove.

In addition, the first member 1126 may include a through hole 1126a, 1126b. The through hole may be composed of a first through hole 1126a and a second through hole 1126b in multiple pieces.

The first and second extensions of the second member, which will be described later, can pass through the first through hole 1126a and the second through hole 1126b, respectively. Through this, a holding force between the second member and the first member can be generated by the repulsive force between the first and second magnetic bodies. In other words, even when the mover tilts, the first carrier and the mover can maintain their positions relative to each other. A second protrusion groove (PH2) can be located between the first through hole 1126a and the second through hole 1126b. By this configuration, the bonding strength between the tilting guide portion 1141 and the first member 1126 is improved, and the deterioration of the tilt accuracy caused by the tilting guide portion 1141 moving within the first carrier can be prevented.

In addition, a second groove (gr2) can be located on the outer surface of the first member 1126. A first magnetic body can be settled in the second groove (gr2). And the outer surface of the first member 1126 can face or be opposed to the inner surface of the second member or the member base. Furthermore, the second magnetic body settled in the second member and the first magnetic body of the first member 1126 can face each other and generate the repulsive force described above. Accordingly, since the first member 1126 presses the tilting guide portion inward or the holder by the repulsive force, the mover can be spaced apart from the third carrier side by a predetermined distance within the first carrier even without current injection into the coil. In other words, a holding force that maintains the position between the mover, the carrier, and the tilting guide portion can be generated by the first magnetic body and the second magnetic body.

In addition, when the first member 1126 is formed integrally with the first carrier 1120, the bonding strength between the first member 1126 and the first carrier 1120 is improved, thereby improving the reliability of the lens assembly. In addition, when formed separately, the ease of assembly and manufacturing of the first member 1126 and the first carrier 1120 can be improved.

In addition, as an embodiment, the first member 1126 may include a first through hole 1126a and a second through hole 1126b as described above. In addition, the first through hole 1126a and the second through hole 1126b may be arranged in parallel in the second direction (Y-axis direction) and may overlap each other. The first member 1126 may further include a first protrusion 1126c and a second protrusion 1126d. The first protrusion 1126c may be in contact with the first carrier side 1121, and the second protrusion 1126d may be in contact with the second carrier side 1122. The first protrusion 1126c may extend in the third direction (Z-axis direction) from one end of the outer surface of the first member. The second protrusion 1126d may extend in the third direction (Z-axis direction) from the other end of the outer surface of the first member. That is, the first protrusion and the second protrusion may extend toward the holder.

In addition, as described above, the carrier wall 1124 according to the embodiment may include a wall 1124a and a carrier extension 1124b. The carrier wall portion 1124 or wall portion 1124a may overlap with the first through hole 1126a and the second through hole 1126b of the first member 1126 in the optical axis direction (Z-axis direction). For example, the carrier wall portion 1124 or wall portion 1124a may partially overlap with the first through hole 1126a and the second through hole 1126b of the first member 1126 in the optical axis direction (Z-axis direction). In addition, a second protrusion groove (PH2) may be positioned between adjacent wall portions 1124a. In addition, the carrier wall portion 1124 or wall portion 1124a may not overlap with the second protrusion groove (PH2) in the optical axis direction (Z-axis direction). By this configuration, the effective area for light reflected and emitted through the optical member positioned between adjacent wall portions 1124a can be increased. Furthermore, the distance between adjacent carrier extension portions 1124b (the distance separated in the second direction) can be reduced along the optical axis direction. By this configuration, the amount of light incident on the optical member can be increased. Furthermore, the carrier extension portion 1124b can sufficiently perform the role of a stopper for the tilt of the holder. In addition, a third carrier hole 1123a can be positioned between adjacent carrier extension portions 1124b. That is, the third carrier hole 1123a and the carrier extension portion 1124b do not overlap in the first direction (X-axis direction) but can be misaligned.

The optical member 1132 can be mounted on the holder. The optical member 1132 can be a right-angled prism as a reflector. In addition, the optical member 1132 can be mounted on the mounting surface of the holder with a bottom surface. Accordingly, the optical member 1132 can have a bottom surface corresponding to the mounting surface of the holder. Furthermore, the bottom surface of the optical member 1132 can be a reflective surface. In addition, the upper surface of the optical member 1132 can be an incident surface on which light is incident. In addition, the back surface of the optical member 1132 can be an exit surface from which light is emitted. In addition, the protrusion of the holder can face the carrier wall portion described below. Furthermore, the protrusion of the holder can overlap with the optical member 1132 in the optical axis direction. Accordingly, in the present embodiment, the protrusion of the holder may not overlap with the carrier wall portion in the optical axis direction. In addition, as described above, the optical member 1132 may be configured to reflect light reflected from the outside (e.g., an object) into the inside of the camera module. As in the embodiment, the optical member 1132 may be configured as a single mirror. In addition, the optical member 1132 may change the path of the reflected light to improve the spatial limitations of the first lens assembly and the second lens assembly. Accordingly, it should be understood that the camera module may provide a high range of magnification by expanding the optical path while minimizing the thickness. In addition, it should be understood that the camera module including the lens assembly according to the embodiment may provide a high range of magnification by expanding the optical path while minimizing the thickness.

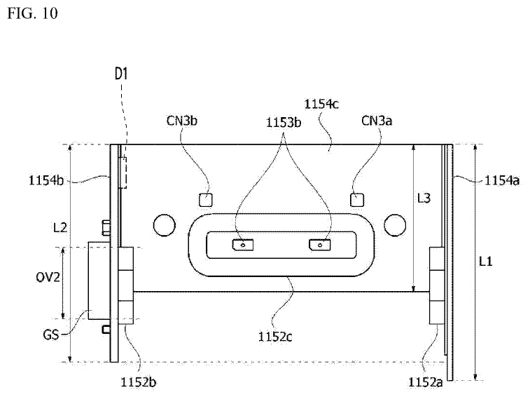

FIG. 9 is a drawing illustrating a first driving portion of the first lens assembly according to the embodiment, and FIG. 10 is a plan view of a driving coil and a first board portion in the first lens assembly according to one embodiment. Referring to FIGS. 9 and 10 and FIGS. 6 to 8, the first driving portion 1150 includes a driving magnet 1151, a driving coil 1152, a hall sensor portion 1153, a first board portion 1154, and a yoke portion 1155.

In addition, as described above, the driving magnet 1151 may include a first magnet 1151a, a second magnet 1151b, and a third magnet 1151c that provide a driving force by electromagnetic force. The first magnet 1151a, the second magnet 1151b, and the third magnet 1151c may each be located on the outer surface of the holder 1131.

In addition, the driving coil 1152 may include a plurality of coils. In an embodiment, the drive coil 1152 may include a first coil 1152a, a second coil 1152b, and a third coil 1152c. The first coil 1152a may be positioned opposite the first magnet 1151a. Accordingly, the first coil 1152a may be positioned in the first carrier hole 1121a of the first carrier side 1121 as described above. In addition, the second coil 1152b may be positioned opposite the second magnet 1151b. Accordingly, the second coil 1152b may be positioned in the second carrier hole 1122a of the second carrier side 1122 as described above.

The first lens assembly according to the embodiment can minimize the occurrence of decent or tilt phenomenon when implementing OIS by controlling the rotation of the mover 1130 along the first axis (X-axis direction) or the second axis (Y-axis direction) by the electromagnetic force between the driving magnet 1151 and the driving coil 1152, thereby providing the best optical characteristics. In addition, according to the embodiment, by implementing OIS through the tilting guide portion 1141 of the rotation portion 1140 arranged between the first carrier 1120 and the mover 1130, the size limitation of the actuator can be eliminated, thereby providing an ultra-slim, ultra-small lens assembly and a camera module including the same.

The first board portion 1154 can include a first board 1154a, a second board 1154b, and a first sub-board 1154c. The first board 1154a and the second board 1154b may be arranged to face each other. And the first sub-board 1154c may be positioned between the first board 1154a and the second board 1154b. In addition, the first board 1154a may be positioned between the first carrier side and the shield can, and the second board 1154b may be positioned between the second carrier side and the shield can. In addition, the first sub-board 1154c may be positioned between the third carrier side and the shield can, and may be the bottom surface of the first board portion 1154. The first board 1154a may be coupled with the first coil 1152a and may be electrically connected. In addition, the first board 1154a may be coupled with the first hall sensor 1153a and may be electrically connected.

The second board 1154b may be coupled and electrically connected to the second coil 1152b. It should also be understood that the second board 1154b may be coupled and electrically connected to the first Hall sensor. The first sub-board 1154c may be coupled and electrically connected to the third coil 1152c. In addition, the first sub-board 1154c may be coupled and electrically connected to the second Hall sensor 1153b.

The yoke portion 1155 may include a third yoke 1155a, a fourth yoke 1155b, and a fifth yoke 1155c. The third yoke 1155a may be positioned within the first mounting groove and may be coupled to the first magnet 1151a. In addition, the fourth yoke 1155b may be positioned within the second mounting groove and coupled with the second magnet 1151b. In addition, the fifth yoke 1155c may be positioned within the third mounting groove and coupled with the third magnet 1151c. These third to fifth yokes 1155a to 1155c allow the first to third magnets 1151a to 1151c to be easily mounted within the first to third mounting grooves and coupled with the carrier.

In the first lens assembly, the first board portion 1154 may be connected to the holder 1131. For example, as described above, the first board portion 1154 may be coupled with the holder 1131. In addition, a drive coil 1152 and a hall sensor 1153 may be arranged on the first board portion 1154. As an example, the first coil 1152a to the third coil 1152b of the drive coil 1152 may be arranged on the first board portion 1154. In addition, the first coil 1152a to the third coil 1152b may be mounted on the first board portion 1154. In addition, the first hall sensor 1153a and the second hall sensor 1153b may be arranged on the first board portion 1154. And the first hall sensor 1153a and the second hall sensor 1153b may be arranged on the first board portion 1154.

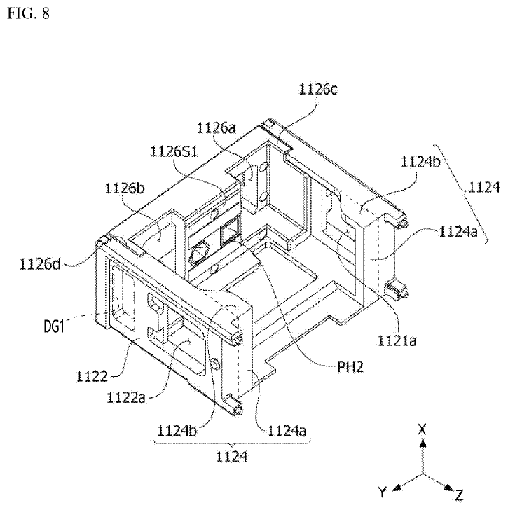

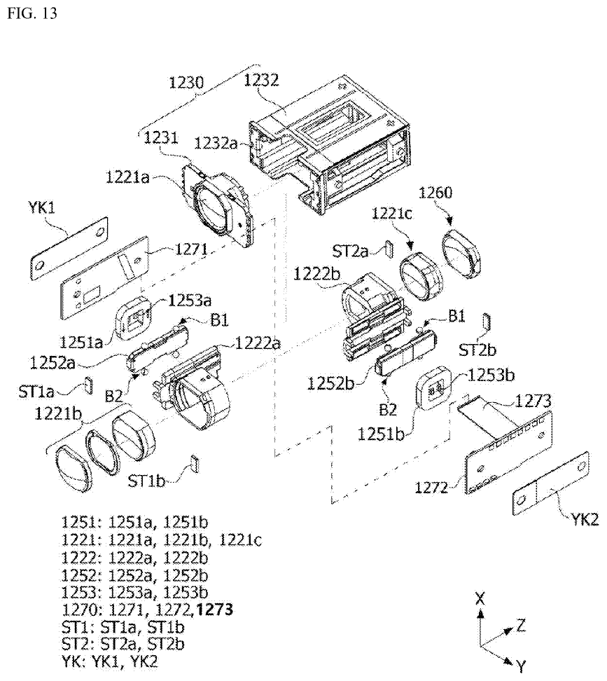

In addition, the first board portion 1154 may be provided without a driver portion (Driver IC). That is, the driver portion (DI) may not be mounted on the first board portion 1154 but may be mounted on the second board portion (1270, FIG. 13). Here, in the past, the first driver portion was arranged on the first board portion 1154 to control the driving of the optical member 1132 of the first lens assembly 1100 through the current control of each coil, and in this case, the first driver portion (DI of FIG. 10) may be separately formed with a driver insertion groove (DG1 of FIG. 8) on the first carrier side portion 1121 of the first carrier 1120 disclosed in FIG. 8 and then coupled. The invention may not form a driver insertion groove of the first carrier 1220 separately, and may not have an additional first driver portion on the first board portion 1154. Accordingly, the first driver portion is removed from the first board portion 1154, so that the freedom of the circuit pattern and design can be improved. In addition, a posture detection sensor (GS) may be arranged on the first board portion 1154. The posture detection sensor (GS) may be mounted on the first board portion 1154. For example, the posture detection sensor (GS) may include various sensors. For example, the posture detection sensor (GS) may include a gyro sensor.

In an embodiment, the first board 1154a and the second board 1154b of the first board portion 1154 may have different thicknesses corresponding to the posture detection sensor (GS) or the driving coil (first and second coils). In the embodiment, a posture detection sensor (GS) may be arranged on the outer side of the second board 1154b. Furthermore, a first coil 1152a to a third coil 1152c may be arranged on the inner side of each of the first board 1154a, the second board 1154b, and the first sub-board 1154c. The posture detection sensor (GS) may be arranged in a different area or a different board portion, and is not limited thereto. The thickness of the first board 1154a may be the same as or different from the thickness of the second board 1154b. In the present embodiment, the thickness of the first board 1154a may be the same as the thickness of the second board 1154b. In this case, the thickness of the first board 1154a and the thickness of the second board 1154b may correspond to the length in the second direction (Y-axis direction). And the thickness of the first sub-board 1154c can correspond to the length in the first direction. The thickness of the first sub-board 1154c can be smaller than the thickness of the first board 1154a or the thickness of the second board 1154b. However, as a modified example, the first sub-board 1154c can be arranged as a flexible substrate. Accordingly, the first sub-board 1154c can be arranged as a thick layer in the area where the third coil 1152c is arranged. As a result, heat generated from the third coil 1152c can be easily dissipated.

First, as mentioned above, the first board portion 1154 may include a first board 1154a, a second board 1154b facing the first board 1154a, and a first sub-board 1154c disposed between the first board 1154a and the second board 1154b. Furthermore, the first board 1154a and the second board 1154a may be disposed in a multi-layer structure, and a layer of a flexible material may be disposed on the inside and a layer of a rigid material may be disposed on the inside or/and the outside. The layers of the flexible material of the first board 1154a and the second board 1154a may be extended or connected to the first sub-board 1154b.

The multi-layer structure of the first board 1154a and the second board 1154a can be formed by laminating copper (Cu) on the outer and inner sides of the layer of copper foil and polyimide, and the layer of polyimide. In addition, the surface of the copper or copper foil layer can be plated or plated, and an insulating plate, a through hole, or a conductor pattern can be formed by an electrochemical reaction inside. A bonding layer can be arranged between the layers, and a cover layer or a solder resist layer can be arranged on the outer surface. Furthermore, the posture detection sensor (GS) and the drive coil (second coil) can overlap at least partly in the horizontal direction (Y-axis direction) (OV1). By this configuration, the heat dissipation generated from the drive coil can be reduced while reducing the sensitivity to shock as described above.

As shown in FIG. 10, a third coil terminal (CN3a, CN3b) may be located on the first sub-board 1152c. For example, the third coil terminal (CN3a, CN3b) may be located on the first sub-board 1152c or the inner side. In addition, the third coil terminal (CN3a, CN3b) may be connected to each end of the third coil 1152c. In addition, the third coil terminal (CN3a, CN3b) may be electrically connected to an external connector. A first coil terminal (not shown) connected to both ends of the first coil may be located on the first board 1154a. A second coil terminal (not shown) connected to both ends of the second coil may be located on the second board 1154b.

The first board 1154a and the second board 1154b may have different lengths. The length (L1) of the first board 1154a in the third direction (Z-axis direction) may be greater than the length (L2) of the second board 1154b in the third direction. Furthermore, the length (L2) of the second board 1154b in the third direction may be greater than the length (L3) of the first sub-board 1154c in the third direction. The first sub-board 1154c may be a flexible or flexibly printed circuit board (FPCB). In addition, the second board 1154b and the first board 1154a may be formed of a flexible or flexibly printed circuit board depending on the region. By this configuration, the first board 1154a and the second board 1154b may be a flexible printed circuit board (RFPCB). In other words, the first board 1154a and the second board 1154b have a multi-layer structure, and malfunctions in which output values change due to external impact or heat generated from a coil may be reduced.

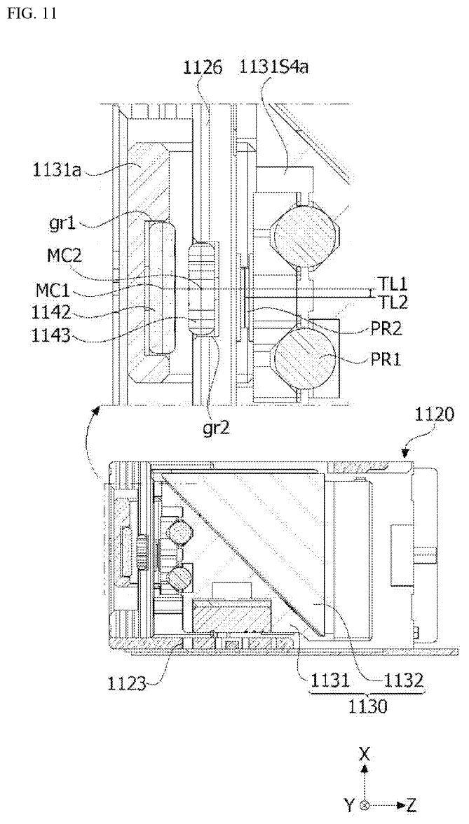

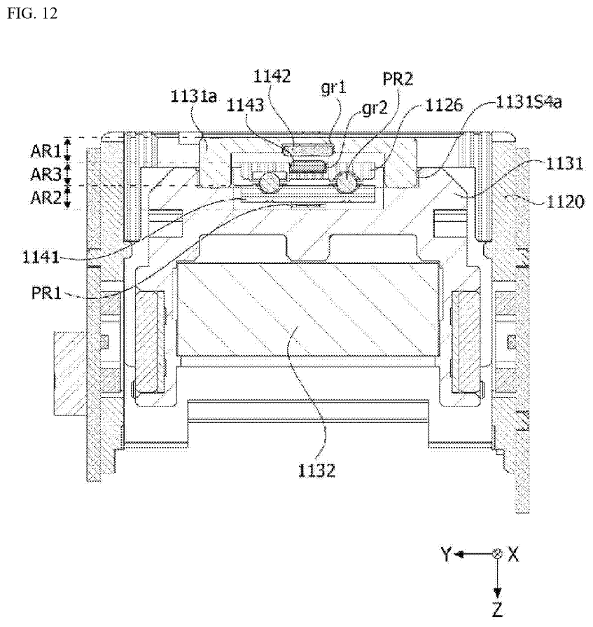

FIG. 11 is a drawing explaining an example of tilting in the Y-axis direction of the first lens assembly of FIG. 6, and FIG. 12 is a cross-sectional view explaining an example of tilting in the X-axis and Z-axis of the first lens assembly of FIG. 6. Referring to FIG. 11, FIG. 12, and FIG. 6, the Y-axis tilt may be performed in the first lens assembly according to the embodiment. That is, OIS may be implemented by rotating in the first direction (X-axis direction). The third magnet 1151c arranged at the bottom of the holder 1131 forms an electromagnetic force with the third coil 1152c to tilt or rotate the mover 1130 in the second direction (Y-axis direction). Specifically, the repulsive force between the second magnetic body 1142 and the first magnetic body 1143 can be transmitted to the second member 1131a and the first member 1126, and finally to the tilting guide portion 1141 arranged between the first member 1126 and the holder 1131. Accordingly, the tilting guide portion 1141 can be pressed by the mover 1130 and the first carrier 1120 by the repulsive force described above.

The second protrusion PR2 may be supported by the first member 1126. At this time, the tilting guide 1141 may rotate or tilt the second protrusion PR2 protruding toward the first member 1126 with respect to the reference axis (or rotation axis), that is, the second direction (Y-axis direction). In other words, the tilting guide 1141 may rotate or tilt the second protrusion PR2 protruding toward the first member 1126 with respect to the reference axis (or rotation axis) in the first direction (X-axis direction). For example, the OIS may be implemented by rotating the mover 1130 at a first angle in the X-axis direction by the first electromagnetic force between the third magnet 1151c and the third coil 1152c arranged on the first sub-board. Conversely, OIS implementation can be achieved by rotating the mover 1130 in the opposite direction of the X-axis at a first angle by the first electromagnetic force between the third magnet 1151c and the third coil 1152c arranged on the first sub-board. The first angle can be ±1° to ±3°.

As shown in FIG. 12, the tilting guide portion 1141 can be positioned on the outer surface of the holder 1131 as described above. In addition, the tilting guide portion 1141 can be seated in the fourth mounting groove 1131S4a of the outer surface. As described above, the fourth mounting groove 1131S4a can include the first region AR1, the second region AR2, and the third region AR3 described above. In the first region AR1, a second member 1131a may be arranged, and the second member 1131a may include a first groove (gr1) formed on an inner surface. In addition, a second magnetic body 1142 may be arranged in the first groove gr1 as described above, and a repulsive force RF2 generated in the second magnetic body 1142 may be transmitted to the fourth mounting groove 1131S4a of the holder 1131 through the second member 1131a. Accordingly, the holder 1131 may apply a force to the tilting guide portion 1141 in the same direction as the repulsive force generated in the second magnetic body 1142. A first member 1126 may be arranged in the second region AR2. The first member 1126 may include a second groove gr2 facing the first groove gr1. In addition, the first member 1126 may include a second protrusion groove PH2 arranged on a surface corresponding to the second groove gr2. In addition, a repulsive force generated from the first magnetic body 1143 may be applied to the first member 1126. Accordingly, the first member 1126 and the second member 1131a may press the tilting guide portion 1141 arranged between the first member 1126 and the holder 1131 through the generated repulsive force. Accordingly, even after the holder is tilted in the X-axis or Y-axis by the current applied to the first and second coils or the third coil 1152c, the coupling (or position) between the holder 1131, the first housing 1120, and the tilting guide portion 1141 may be maintained. The tilting guide portion 1141 may be arranged in the third region AR3. The tilting guide portion 1141 may include the first protrusion PR1 and the second protrusion PR2 as described above. At this time, the first protrusion PRI and the second protrusion PR2 may be respectively arranged on the base. Likewise, in other embodiments described below, the first protrusion PRI and the second protrusion PR2 may be variously positioned on the facing surfaces of the base.

In the first lens assembly according to various embodiments below, the electromagnetic force may generate force in the described direction to move the mover, or may generate force in a different direction to move the mover in the described direction. That is, the direction of the described electromagnetic force refers to the direction of the force generated by the magnet and the coil to move the mover. For example, the first electromagnetic force may act in the third direction or in the opposite direction to the third direction. In addition, the center MC1 of the second magnetic body 1142 and the center MC2 of the first magnetic body 1143 may be arranged in parallel along the third direction (Z-axis direction). In other words, the center line TL1 connecting the center MC1 of the second magnetic body 1142 and the center MC2 of the first magnetic body 1143 may be parallel to the third direction (Z-axis direction). In addition, the bisector TL2 that bisects the second protrusion PR2 and corresponds to the third direction (Z-axis direction) may be parallel to the center line TL1 (or bisector). In other words, the bisector TL2 may be a line that bisects the second protrusion PR2 in the first direction (X-axis direction), and may be plural.

As an example, the bisector TL2 may be positioned apart from the center line TL1 in the first direction (X-axis direction). The bisector TL2 may be positioned above the center line TL1. With this configuration, the distance between the third coil 1152c or the third magnet 1151c increases, so that the holder can tilt more accurately in two axes. Furthermore, the position of the holder can be maintained the same when no current is applied to the coil. More specifically, since the center MC1 of the second magnetic body 1142 and the center MC2 of the first magnetic body 1143 are spaced apart from the bisector TL2 and the first direction (X-axis direction), the force (e.g., repulsive force) between the second magnetic body 1142 and the first magnetic body 1143 can act in the first direction (X-axis direction) apart from the bisector TL2 corresponding to the optical axis. And momentum is generated in the mover 1130 by this force. However, if the center MC1 of the second magnetic body 1142 and the center MC2 of the first magnetic body 1143 are located on the bisector TL2, there is a problem that the calibration progress, the tilting guide portion, and the position of the second magnetic body 1142 are not maintained after tilting. That is, the first lens assembly according to the embodiment prevents the center MC1 of the second magnetic body 1142 and the center MC2 of the first magnetic body 1143 from being positioned on the bisector TL2, so that the tilting guide portion and the position of the second magnetic body 1142 can be maintained after tilting or rotating. In another embodiment, the center MC1 of the second magnetic body 1142 and the center MC2 of the first magnetic body 1143 can be positioned apart from each other in the first direction (X-axis direction).

In addition, the center MC1 of the second magnetic body 1142 and the center MC2 of the first magnetic body 1143 may not be positioned on the bisector TL2. For example, the center MC1 of the second magnetic body 1142 and the center MC2 of the first magnetic body 1143 may be located above the bisector TL2. As a result, the separation distance between the third coil 1152c or the third magnet 1151c increases, so that the holder can tilt more accurately in two axes. Furthermore, the position of the holder can be maintained the same when no current is applied to the coil.

In addition, the second magnetic body 1142 and the first magnetic body 1143 may have different lengths in the first direction (X-axis direction). The second magnetic body 1142 that is combined with the second member 1131a and tilted together with the mover 1130 may have a larger area than the area of the first magnetic body 1143. For example, the second magnetic body 1142 may have a longer length in the first direction (X-axis direction) than the length of the first magnetic body 1143 in the first direction (X-axis direction). In addition, the second magnetic body 1142 may have a longer length in the second direction (Y-axis direction) than the length of the first magnetic body 1143 in the second direction (Y-axis direction). In addition, the first magnetic body 1143 may be positioned within an imaginary straight line extending from both ends of the second magnetic body 1142 in the third direction. By this configuration, when tilting or rotating, even if one magnetic body (e.g., the second magnetic body) is tilted, it is easy to prevent a force other than a vertical force from being generated due to the tilt. That is, even if the second magnetic body is tilted up and down together with the mover 1130, it may not receive a force (e.g., a repulsive force or an attractive force) opposing the tilt from the first magnetic body 1143. As a result, the driving efficiency may be improved.

The first lens assembly may perform an X-axis tilt. That is, OIS may be implemented while the mover 1130 tilts or rotates in the Y-axis direction. As an example, the first magnet 1151a and the second magnet 1151b disposed in the holder 1131 may form an electromagnetic force with the first coil 1152a and the second coil 1152b, respectively, to tilt or rotate the tilting guide portion 1141 and the mover 1130 with respect to the first direction (X-axis direction). Specifically, the repulsive force between the second magnetic body 1142 and the first magnetic body 1143 may be transmitted to the first member 1126 and the holder 1131, and ultimately to the tilting guide portion 1141 disposed between the holder 1131 and the first member 1126. Accordingly, the tilting guide portion 1141 may be pressed by the mover 1130 and the first carrier 1120 by the repulsive force described above. And the first protrusion PRI may be spaced apart in the first direction (X-axis direction) and supported by the first protrusion groove (PH1) formed in the fourth fixing groove 1131S4a of the holder 1131. In addition, as an embodiment, the tilting guide portion 1141 may rotate or tilt the first protrusion PR1 protruding toward the holder 1131 (for example, toward the third direction) with respect to the reference axis (or rotation axis), that is, the first direction (X-axis direction). For example, OIS may be implemented by rotating the mover 1130 at a second angle in the Y-axis direction by the second electromagnetic force between the first and second magnets 1151a, 1151b and the first and second coils 1152a and 1152b arranged on the first and second boards. In addition, the OIS can be implemented by rotating the mover 1130 at a second angle in the Y-axis direction by the second electromagnetic force between the first and second magnets 1151a, 1151b and the first and second coils 1152a and 1152b arranged on the first and second boards. The second angle can be ±1° to 3°.

In addition, as described above, the electromagnetic force by the first and second magnets 1151a, 1151b and the first and second coils 1152a and 1152b can act in the third direction or in the opposite direction to the third direction. For example, the electromagnetic force can be generated in the third direction (Z-axis direction) at the left side of the mover 1130 and can act in the opposite direction to the third direction (Z-axis direction) at the right side of the mover 1130. Accordingly, the mover 1130 can rotate based on the first direction. Or, it can move along the second direction. In this way, the first lens assembly according to the embodiment can minimize the occurrence of decent or tilt phenomenon and provide the best optical characteristics when implementing OIS by controlling the rotation of the mover 1130 in the first direction (X-axis direction) or the second direction (Y-axis direction) by the electromagnetic force between the driving magnet in the holder and the driving coil arranged in the first carrier. In addition, as described above, ‘Y-axis tilt’ means rotating or tilting in the first direction (X-axis direction), and ‘X-axis tilt’ means rotating or tilting in the second direction (Y-axis direction).

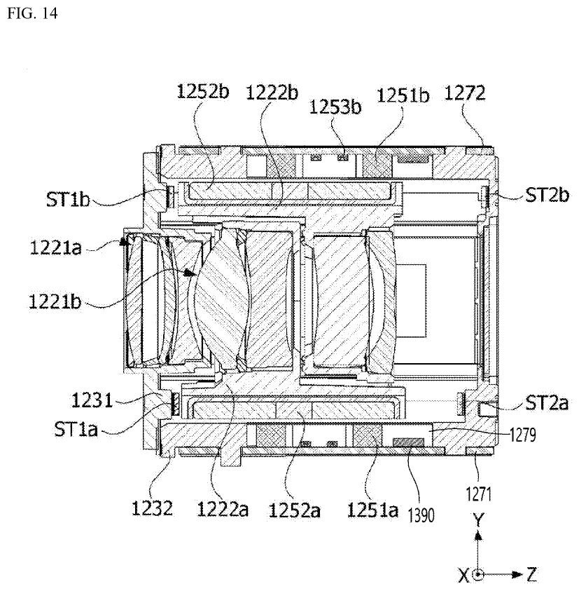

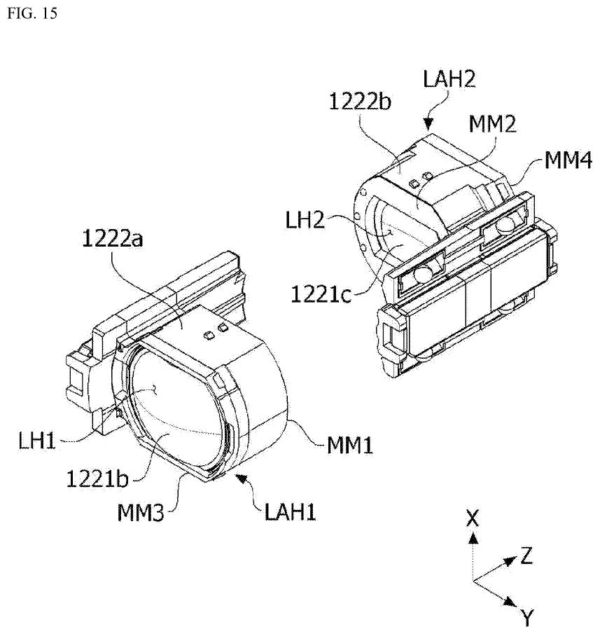

FIG. 13 is an exploded perspective view of a second lens assembly according to an embodiment, FIG. 14 is a detailed side cross-sectional view of the second lens assembly of FIG. 5, and FIG. 15 is an exploded perspective view of the first and second lens holders of the second assembly according to an embodiment.

Referring to FIGS. 13 to 15, the second lens assembly 1200 according to the embodiment may include a lens portion 1220, a second carrier 1230, a second driving portion 1250, a rear optical portion 1260, a second board portion 1270, a bonding member 1280, a stopper portion (ST), and a yoke portion (YK). Furthermore, the second lens assembly 1200 may further include a second shield can (not shown), an elastic portion (not shown), and a bonding member (not shown). In addition, the second lens assembly 1200 may be a separate member from the image sensor and base member described below, or may include the same. Hereinafter, a main board or circuit board 1300 separate from the second lens assembly 1200 is described as including the image sensor and base member. The circuit board 1300 and the image sensor may be a sensor module 1360.

The lens portion 1220 may move along the third direction (Z-axis direction or optical axis direction). Accordingly, the AF function and zoom function described above may be performed. The lens portion 1220 may be located within the second carrier 1230. Accordingly, at least a portion of the lens portion 1220 may move along the optical axis direction or the third direction (Z-axis direction) within the second carrier 1230.

Specifically, the lens portion 1220 may include a lens group 1221 and a moving assembly 1222. The lens group 1221 may include at least one lens. In addition, the lens group 1221 may be plural, but the following description will be based on one.

The lens group 1221 is coupled with the moving assembly 1222 and may move in a third direction (Z-axis direction) by an electromagnetic force generated from the fourth magnet 1252a and the fifth magnet 1252b coupled to the moving assembly 1222. The lens group 1221 may include a first lens group 1221a, a second lens group 1221b, and a third lens group 1221c. The first lens group 1221a, the second lens group 1221b, and the third lens group 1221c may be sequentially arranged along the optical axis direction. The lens group 1221 may further include a fourth lens group 1221d. The fourth lens group 1221d may be arranged at the rear end or sensor side of the third lens group 1221c.

The first lens group 1221a may be fixed by being combined with the second-first carrier. In other words, the first lens group 1221a may not move along the optical axis direction. The second lens group 1221b may be combined with the first lens assembly 1222a and may move in the third direction or the optical axis direction. Magnification adjustment may be performed by moving the first lens assembly 1222a and the second lens group 1221b.

The third lens group 1221c can be combined with the second lens assembly 1222b and moved in the third direction or the optical axis direction. Focus adjustment or auto-focusing can be performed by moving the third lens group 1221c. However, the number of lens groups is not limited, and the fourth lens group 1221d described above may be absent, or additional lens groups other than the fourth lens group 1121d may be arranged.

The moving assembly 1222 may include an opening area surrounding the lens group 1221. This moving assembly 1222 is used interchangeably with the lens assembly. In addition, the moving assembly 1222 may be combined with the lens group 1221 in various ways. In addition, the moving assembly 1222 may include a groove on the side, and may be coupled with the fourth magnet 1252a and the fifth magnet 1252b through the groove. A coupling member, etc. may be applied to the groove.

The moving assembly 1222 may be coupled with an elastic member (not shown) at the top and rear ends. Accordingly, the moving assembly 1222 may be supported by the elastic member (not shown) while moving in the third direction (Z-axis direction). That is, the position of the moving assembly 1222 may be maintained in the third direction (Z-axis direction). The elastic member (not shown) may be made of various elastic elements such as a plate spring. The moving assembly 1222 may be positioned within the second carrier 1230 and may include a first lens assembly 1222a and a second lens assembly 1222b. The area where the third lens group is mounted in the second lens assembly 1222b may be located at the rear end or sensor side of the first lens assembly 1222a. In other words, the area where the third lens group 1221c is mounted in the second lens assembly 1222b may be located between the area where the second lens group 1221b is mounted in the first lens assembly 1222a and the image sensor. The first lens assembly 1222a and the second lens assembly 1222b may each be mounted on the inner side of the second-2 carrier. For example, the recess where the ball is mounted in the first lens assembly 1222a may be positioned facing the first side. And the recess where the ball is mounted in the second lens assembly 1222b may be positioned facing the second side. A detailed description thereof will be described later.

And a second driving magnet may be mounted on the outer surface of the first lens assembly 1222a and the second lens assembly 1222b. For example, a fifth magnet 1252b may be mounted on the outer surface of the second lens assembly 1222b. A fourth magnet 1252a may be mounted on the outer surface of the first lens assembly 1222a. A second carrier 1230 may be positioned between the lens portion 1220 and the second shield can (not shown). And the second carrier 1230 may be positioned to surround the lens portion 1220.

The second carrier 1230 may include a second-1 carrier 1231 and a second-2 carrier 1232. The 2-1 carrier 1231 is coupled with the 1st lens group 1221 a and can also be coupled with the above-described 1st lens assembly. The 2-1 carrier 1231 can be positioned in front of the 2-2 carrier 1232. And the 2-2 carrier 1232 can be positioned at the rear end of the 2-1 carrier 1231. The lens portion 1220 can be mounted inside the 2-2 carrier 1232.

The 2nd carrier 1230 (or the 2-2 carrier (1232)) can have a hole formed on the side. The 4th coil 1251a and the 5th coil 1251b can be arranged in the hole. The hole can be positioned to correspond to the groove of the above-described moving assembly 1222. As an example, the second carrier 1230 (in particular, the second-second carrier (1232)) may include two side portions 1232a that are opposite to each other or symmetrical in the third direction. The second driving coil 1251 may be positioned on the two side portions 1232a, and the second board portion 1270 may be mounted on the outer side thereof. In other words, the third and fourth boards 1271, 1272 may be positioned on the outer side portions of the two side portions. In addition, the second carrier 1230 may include a bottom portion, and may be connected to the two side portions 1232a.

For example, the first and second guide grooves facing the recesses (the mounting grooves in which the first and second balls are mounted) of the first lens assembly 1222a may be positioned on the first side portion. And the first and second guide grooves facing the recesses of the second lens assembly 1222b may be located on the second side. At this time, a separate member (e.g., a guide portion) including the first and second guide grooves may be a structure combined with the second-second carrier 1232. However, in the present embodiment, the first and second guide grooves are described based on an integral structure formed on the second-second carrier 1232. Furthermore, as in other examples, the first guide portion and the second guide portion may be positioned to correspond to each other. For example, the first guide portion and the second guide portion may be positioned to face each other with respect to the third direction (Z-axis direction). In addition, the first guide portion and the second guide portion may overlap each other at least partially in the second direction (Y-axis direction). The first guide portion and the second guide portion may include at least one groove (e.g., a guide groove) or recess. And the first ball B1 or the second ball B2 may be seated in the groove or recess. Accordingly, the first ball B1 or the second ball B2 can move in the third direction (Z-axis direction) within the guide groove of the first guide portion or the guide groove of the second guide portion. Or, the first ball B1 or the second ball B2 can move in the third direction along the rail formed on the inside of both sides 1232a of the second carrier 1230. Accordingly, the first lens assembly 1222a and the second lens assembly 1222b can move in the third direction.

According to an embodiment, the first ball B1 may be disposed on an upper side of the first lens assembly 1222a or the second lens assembly 1222b. And the second ball B2 may be disposed on a lower side of the first lens assembly 1222a or the second lens assembly 1222b. For example, the first ball B1 may be disposed on an upper side of the second ball B2. Therefore, depending on the position, the first ball B1 may at least partially overlap the second ball B2 along the first direction (X-axis direction). A fourth magnet and a fourth coil may be disposed on a first side of the second carrier 1230, and a fifth magnet and a fifth coil may be disposed on a second side. And the fifth magnet 1252b may be disposed to face the fifth coil 1251b. In addition, the fourth magnet 1252a may be positioned to face the fourth coil 1251a.

The elastic member (not shown) may include a first elastic member (not shown) and a second elastic member (not shown). The first elastic member (not shown) may be coupled with the upper surface of the moving assembly 1222. The second elastic member (not shown) may be coupled with the lower surface of the moving assembly 1222. In addition, the first elastic member (not shown) and the second elastic member (not shown) may be formed as a plate spring as described above. In addition, the first elastic member (not shown) and the second elastic member (not shown) may provide elasticity for the movement of the moving assembly 1222. However, it is not limited to the above-described position, and the elastic member may be arranged in various positions.

And the second driving portion 1250 can provide a driving force to move the lens portion 1220 in the third direction (Z-axis direction). This second driving portion 1250 can include a second driving coil 1251 and a second driving magnet 1252. Furthermore, the second driving portion 1250 can further include a second Hall sensor portion. The second Hall sensor portion 1253 can include at least one fourth Hall sensor 1253a and can be located on the inner or outer side of the second driving coil 1251.

The moving assembly can move in the third direction (Z-axis direction) by the electromagnetic force formed between the second driving coil 1251 and the second driving magnet 1252. The second driving coil 1251 can include a fourth coil 1251a and a fifth coil 1251b. The fourth coil 1251a and the fifth coil 1251b may be placed in a hole formed on the side of the second carrier 1230. And the fourth coil 1251a and the fifth coil 1251b may be electrically connected to the second board portion 1270. Accordingly, the fourth coil 1251a and the fifth coil 1251b may be supplied with current, etc. through the second board portion 1270.

The second driving magnet 1252 may include a fourth magnet 1252a and a fifth magnet 1252b. The fourth magnet 1252a and the fifth magnet 1252b may be placed in the grooves of the moving assembly 1222 described above, and may be positioned to correspond to the fourth coil 1251a and the fifth coil 1251b. The rear optical portion 1260 may include a lens made of plastic or glass.

The base portion or base member of the circuit board 1300 may be positioned between the lens portion 1220 and the image sensor (IS). Components such as a filter may be fixed to the base member. In addition, the base member may be arranged to surround the image sensor described above. By this configuration, the image sensor is free from foreign substances, etc., so that the reliability of the device may be improved. However, in some drawings below, this is removed and described. However, it may not be limited to this structure.

In addition, the second lens assembly 1200 may be a zoom actuator and an AF Auto Focus actuator. For example, the second lens assembly may support one or more lenses and move the lenses according to a control signal of a predetermined control portion to perform at least one of an auto focus function and a zoom function. In addition, the second lens assembly may be a fixed zoom or a continuous zoom. For example, the second lens assembly may provide movement of the lens group 1221. In addition, the second lens assembly may be composed of a plurality of lens assemblies. For example, the second lens assembly may be configured to have at least one of a third lens assembly (not shown), and a guide pin (not shown) in addition to the first lens assembly 1222a, the second lens assembly 1222b. The above-described contents may be applied to this. Accordingly, the second lens assembly may perform a high-magnification zooming function through the second driving portion. For example, the first lens assembly 1222a and the second lens assembly 1222b may be moving lenses that move via the second driving portion and the guide pin (not shown), and the third lens assembly (not shown) may be a fixed lens, but is not limited thereto. For example, the third lens assembly (not shown) may perform the function of a light collector that focuses light at a specific location, and the first lens assembly may perform the function of a variator that refocuses the image focused by the third lens assembly (not shown), which is a light collector, at another location. Meanwhile, in the first lens assembly, the distance to the subject or the image distance may change significantly, so that the magnification may change significantly, and the first lens assembly, which is a variator, may play an important role in the focal length or magnification change of the optical system. Meanwhile, the point of view focused by the first lens assembly, which is a variator, may differ slightly depending on the location. Accordingly, the second lens assembly may perform a position compensation function for the image focused by the variator. For example, the second lens assembly may perform a compensator function that accurately focuses the imaged point in the second lens assembly 1222b, which is a variable, on the actual image sensor position. However, the configuration of the present embodiment will be described based on the following drawings.

The image sensor may be located on the inside or outside of the second lens assembly. In an embodiment, the image sensor may be located on the outside of the second lens assembly as illustrated. For example, the image sensor may be located on the inside of the circuit board. The image sensor may receive light and convert the received light into an electrical signal. In addition, the image sensor may be formed of a plurality of pixels in an array form. And the image sensor may be located on the optical axis.

The second board portion 1270 may be in contact with the side of the second carrier. For example, the second board portion 1270 is positioned on the outer surface (first side) of the first side and the outer surface (second side) of the second side of the second carrier, particularly, the 2-2 carrier, and can be in contact with the first side and the second side. The stopper portion (ST) includes a first stopper ST1 arranged at one end of the 2-2 carrier 1232 and a second stopper ST2 arranged at the other end. The first stopper ST1 and the second stopper ST2 can be arranged sequentially along the optical axis direction.

The first stopper ST1 may be arranged in multiple numbers on the movement path of the first lens assembly and the movement path of the second lens assembly, respectively. For convenience, they are described as the 1-1 stopper ST1a and the 1-2 stopper ST1b. Likewise, the second stopper ST2 may be arranged in multiple pieces, respectively, on the movement path of the first lens assembly and the movement path of the second lens assembly. In addition, the second-first stopper ST2a and the second-second stopper ST2b are described.

The first-first stopper ST1a and the second-first stopper ST2a may be positioned on the movement path of the first lens assembly. The first-second stopper ST1b and the second-second stopper ST2b may be positioned on the movement path of the second lens assembly. The first-first stopper ST1a and the first-second stopper ST1b may overlap in the second direction. Alternatively, the first-first stopper ST1a and the first-second stopper ST1b may be misaligned in the second direction. The second-first stopper ST2a and the second-second stopper ST2b may be positioned misaligned in the second direction. The distance between the first-first stopper ST1a and the second-first stopper ST2a in the third direction may be smaller than the distance between the first-second stopper ST1b and the second-second stopper ST2b. This is a configuration that reflects the point that the movable distance (stroke) of the first lens assembly is smaller than the movable distance (stroke) of the second lens assembly.

In an embodiment, the second yoke portion or the yoke portion (YK) may be arranged on the outside of the second driving portion. For example, the yoke portion (YK) may be arranged on the outside of the fourth and fifth coils. The second yoke portion (YK) may include the first yoke YK1 and the second yoke YK2. The first yoke YK1 and the second yoke YK2 may be positioned opposite to each other. For example, the first yoke YK1 and the second yoke YK2 may be positioned corresponding to each other with respect to the optical axis. The first yoke YK1 may be positioned adjacent to the fourth coil 1251a. The second yoke YK2 may be positioned adjacent to the fifth coil 1251b. The fourth coil 1251a and the fifth coil 1251b may be positioned inside the first yoke YK1 and the second yoke YK2. In addition, the first yoke YK1, the fourth coil 1251a, the fifth coil 1251b, and the second yoke YK2 may be sequentially positioned in one direction (e.g., the second direction). The first yoke YK1 can form an attractive force with the fourth magnet. In addition, the second yoke YK2 can form an attractive force with the fifth magnet. Accordingly, the posture of the first and second lens assemblies can be maintained.

The first yoke YK1 and the second yoke YK2 may have varying thicknesses in some areas. By this configuration, it is possible to suppress the magnetic force generated from the fourth and fifth magnets or the fourth and fifth coils from affecting other magnets and coils. For example, the first yoke YK1 can suppress the magnetic force generated by the fourth magnet from being applied to the fifth magnet and the fifth coil.

In the camera device according to the embodiment, the second driving portion may provide a driving force to move the first lens assembly 1222a and the second lens assembly 1222b of the lens portion 1220 along the third direction (Z-axis direction). As described above, the second driving portion may include the second driving coil 1251 and the second driving magnet 1252. Then, the lens portion 1220 may move along the third direction (Z-axis direction) by the electromagnetic force formed between the second driving coil 1251 and the second driving magnet 1252.

At this time, the fourth coil 1251a and the fifth coil 1251b may be placed in holes formed on both sides of the second carrier 1230. Then, the fifth coil 1251b may be electrically connected to the third board 1271. The fourth coil 1251a may be electrically connected to the fourth board 1272. Accordingly, the fourth coil 1251a and the fifth coil 1251b may receive a driving signal (e.g., current) through the driver portion 1390 of the second board portion 1270.

The driver portion 1390 may be arranged on the inner side of the second board portion 1270, preferably arranged on the inner side of the third board 1271, and may be accommodated in a groove (not shown) on one side of the second carrier 1230. The driver portion 1390 may have three or more communication channels, for example, four or more communication channels, and may control the driving of both the first lens assembly 1100 and the second lens assembly 1200.

At this time, the first lens assembly 1222a on which the fourth magnet 1252a is mounted can move along the third direction (Z-axis direction) by the electromagnetic force between the fourth coil 1251a and the fourth magnet 1252a. In addition, the second lens group 1221b mounted on the first lens assembly 1222a can move along the third direction. In addition, the second lens assembly 1222b on which the fifth magnet 1252b is mounted can move along the third direction (Z-axis direction) by the electromagnetic force between the fifth coil 1251b and the fifth magnet 1252b. In addition, the third lens group 1221c mounted on the second lens assembly 1222b can also move along the third direction.

Accordingly, as described above, the focal length or magnification of the optical system can be changed by moving the second lens group 1221b and the third lens group 1221c. As an example, the magnification can be changed by moving the second lens group 1221b. In other words, zooming can be performed. In addition, the focus can be adjusted by moving the third lens group 1221c. In other words, auto focusing can be performed. With this configuration, the second lens assembly can be a fixed zoom or a continuous zoom.

Referring to FIG. 15, the first lens assembly 1222a and the second lens assembly 1222b can be spaced apart in the optical axis direction (Z-axis direction). And the first lens assembly 1222a and the second lens assembly 1222b can move along the optical axis direction (Z-axis direction) by the second driving portion. For example, an auto focus or zoom function can be performed by the movement of the first lens assembly 1222a and the second lens assembly 1222b. In addition, the first lens assembly 1222a can include a first lens holder (LAH1) that holds and combines the second lens group 1221b. The first lens holder (LAH1) can be combined with the second lens group 1221b. In addition, the first lens holder (LAH1) can include a first lens hole (LH1) for accommodating the second lens group 1221b. That is, a second lens group 1221b including at least one lens can be arranged in the first lens hole (LH1). The first lens holder (LAH1) is identical to the receiving portion and is used interchangeably. And the second lens assembly 1222b may include a second lens holder (LAH2) that holds and combines the third lens group 1221c. In addition, the second lens holder (LAH2) may include a second lens hole (LH2) for receiving the third lens group 1221c. That is, at least one lens may be arranged in the second lens hole (LH2).

As an example, each of the first lens assembly 1222a and the second lens assembly 1222b may include an outer surface adjacent to each other. The first lens assembly 1222a may include a first outer surface MM1, and the second lens assembly 1222b may include a second outer surface MM2. The first outer side surface MM1 may be the bottom surface of the first lens holder LAH1 based on the optical axis direction (Z-axis direction). In addition, the third outer side surface MM3 described later may be the top surface of the first lens holder LAH1. In addition, the second outer side surface MM2 may be the top surface of the second lens holder LAH2, and the fourth outer side surface MM4 may be the bottom surface of the second lens holder LAH2.

In addition, the first outer side surface MM1 and the second outer side surface MM2 may overlap at least partially in the optical axis direction (Z-axis direction). In an embodiment, the first outer side surface MM1 to the fourth outer side surface MM4 may overlap at least partially in the optical axis direction (Z-axis direction). For example, a bonding member (not shown) may contact at least one of the first outer side surface MM1 and the second outer side surface MM2.

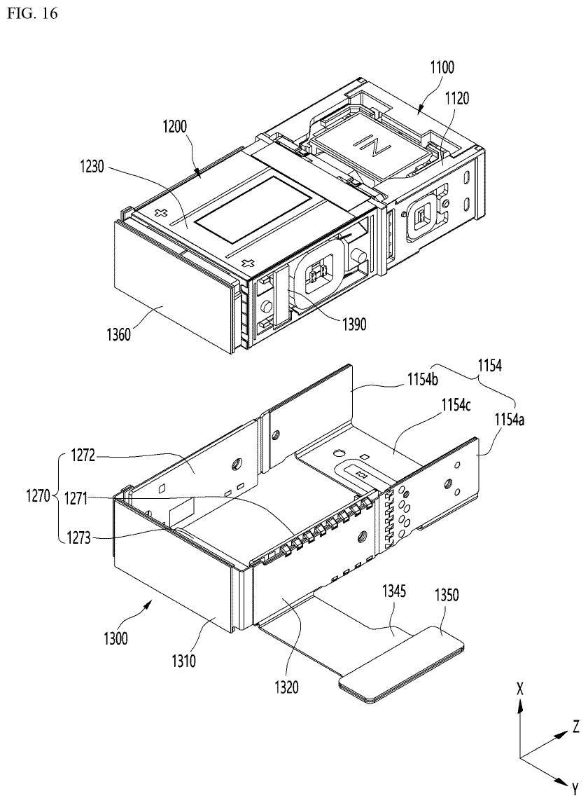

A camera module according to a first embodiment of the invention will be described with reference to FIGS. 16 to 27. Referring to FIGS. 16 to 24, a circuit board 1300 according to the embodiment may include a sensor board portion 1310 on which an image sensor (IS) is arranged, a first circuit board portion 1320 and a second circuit board portion 1330 that are bent in a direction facing each other from both ends of the sensor board portion 1310. An image sensor (IS) may be mounted on an inner surface of the sensor board portion 1310 and may be electrically connected to the image sensor (IS). The above sensor board portion 1310 is located at the rear end of the second lens assembly 12000, and at least one optical filter (e.g., infrared, etc.) can be arranged on the image sensor (IS). Here, the circuit board 1300 is used interchangeably with the main board described below.

In addition, the first circuit board portion 1320 can be located at the first side of the second lens assembly 1200 or the second carrier 1230. In particular, the first circuit board portion 1320 is adjacent to the fourth coil 1251a located adjacent to the first side, and can be easily electrically connected to the third board 1171. In addition, the second circuit board portion 1330 can be located at the second side of the second lens assembly 1200 or the second carrier 1230. The second circuit board portion 1330 is located at the second side. The adjacent fifth coil 1251b may be adjacent and may be easily electrically connected to the fourth board 1172.

The second board portion 1170 includes a third board 1171 and a fourth board 1272, and the third board 1171 and the fourth board 1272 are electrically connected to the circuit board 1300 and may be electrically connected by the second sub-board 1173. The second sub-board 1173 of the second board portion 1170 may be located at the bottom of the second lens assembly 1200. The third board 1171 is arranged between the second carrier 1230 and the first circuit board portion 1320, and the fourth board 1272 is arranged between the second carrier 1230 and the second circuit board portion 1330.

The first board 1154a and the second board 1154b of the first board portion 1154 are arranged on both sides of the first carrier 1120, and the first sub-board 1154c can be arranged on the bottom of the first carrier 1120. The first board 1154a is positioned on the object side of the first circuit board portion 1320 and can be electrically connected to the first circuit board portion 1320. The first board 1154a can be electrically connected to the second board portion 1270 through the first circuit board portion 1320. The second board 1154b is positioned on the object side of the second circuit board portion 1330 and can be electrically connected to the second circuit board portion 1330. The second board 1154b may be electrically connected to the second board portion 1270 through the second circuit board portion 1330. The first board 1154a and the second board 1154b of the first board portion 1154 may be electrically connected by the first sub-board 1154c.

The first embodiment of the invention may have a driver portion 1390 as a single driver IC to control the driving of the first and second lens assemblies 1100, 1200. The driver portion 1390 may be arranged on the inner side of the third board 1371 of the second board portion 1370 and may be accommodated in the receiving groove (1279, FIG. 14) of the first side of the second carrier 1230. As another example, the driver portion 1390 may be placed on the fourth board 1272.

Since the driver portion 1390 is placed on the second board 1270, electrical connection with the main board, the circuit board 1300, may be facilitated, and the communication path with the circuit board 1300 may be reduced. In addition, since the driver portion 1390 is placed on the inner side of the first circuit board portion 1320 from which the connector board 1350 extends or on a board adjacent to the first circuit board portion 1320, the communication path with the connector board 1350 may be reduced.

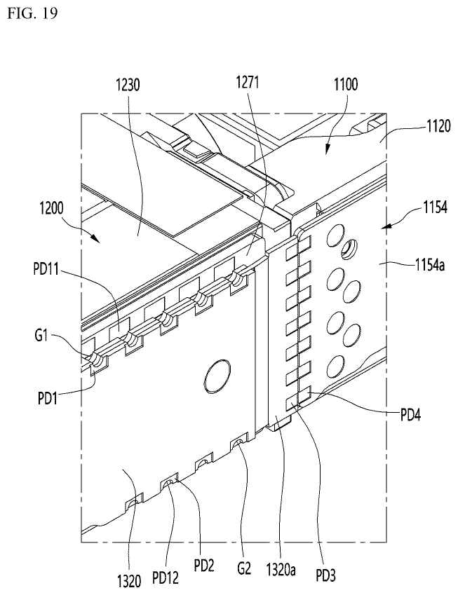

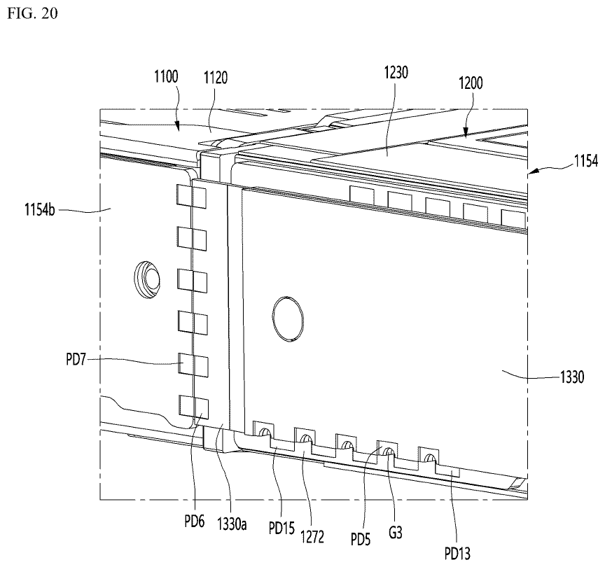

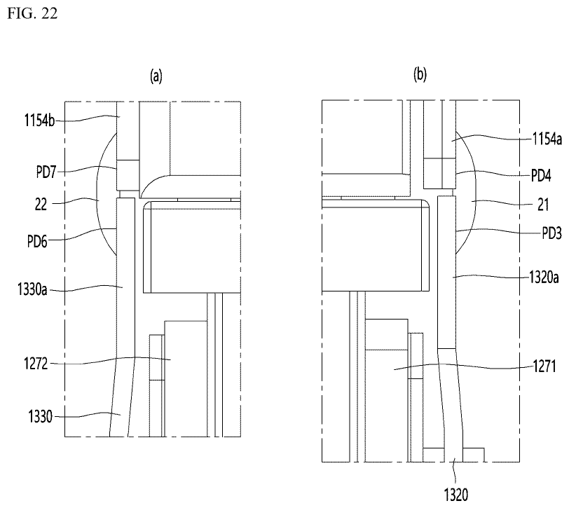

As shown in FIG. 19, FIG. 20 and FIG. 22, the other end of the first board 1154a of the first board portion 1154 and one end of the first circuit board portion 1320 of the circuit board 1300 may correspond to or face each other. Here, the other end of the first board 1154a is closer to the sensor side than the object side, and one end of the first circuit board portion 1320 is closer to the object side than the sensor side. A plurality of first and second bonding pads (PD11, PD12) are exposed on the upper and lower outer sides of the third board 1271 of the second board portion 1270, and the plurality of first and second bonding pads (PD11, PD12) may be arranged in the optical axis direction. The exposure of the first and second bonding pads (PD11, PD12) is an area where the outer layer of the third board 1271 is open. Here, the optical axis direction may be a direction from the object side toward the sensor side or a direction parallel to the optical axis.

A plurality of first pads PDI are arranged on the upper outer side of the first circuit board portion 1320, and may be arranged at positions corresponding to each of the plurality of first bonding pads PD11. A plurality of second pads PD2 are arranged on the lower outer side of the first circuit board portion 1320, and may be arranged at positions corresponding to each of the plurality of second bonding pads PD12. The exposed portions of the first and second pads (PD1, PD2) are areas where at least the outer layer of the first circuit board portion 1320 is open. Here, the upper part of the third board 1271 and the upper part of the first circuit board portion 1320 are areas adjacent to the outer cover of the mobile terminal or the outer side of the mobile body. The upper part of the third board 1271 and the lower part of the first circuit board portion 1320 are located in opposite directions to the upper part of the third board 1271 and the upper part of the first circuit board portion 1320.

As shown in FIG. 19, a plurality of first and second bonding grooves G1 and G2 are arranged on the upper and lower parts of the first circuit board portion 1320, and the first bonding groove G1 may be concave from the upper part of the first circuit board portion (1320) to the lower part, and the second bonding groove G2 may be concave from the lower part of the first circuit board portion 1320 to the upper part. The shape of each of the first and second bonding grooves G1 and G2 may be a hemispherical shape or a polygonal shape. The first bonding groove G1 and the first bonding pad PD1 may correspond to each other or overlap in a horizontal direction (i.e., a direction perpendicular to the optical axis). The second bonding groove G2 and the second bonding pad PD12 may correspond to each other or overlap in a horizontal direction (i.e., a direction perpendicular to the optical axis).

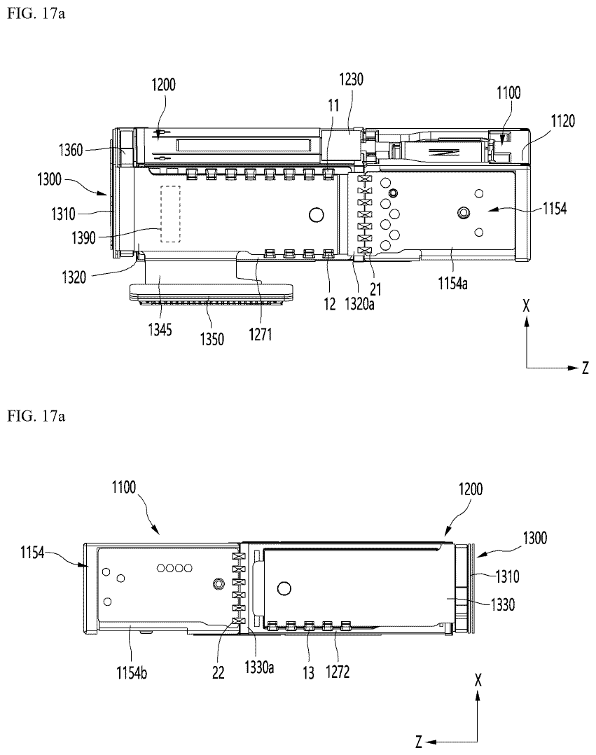

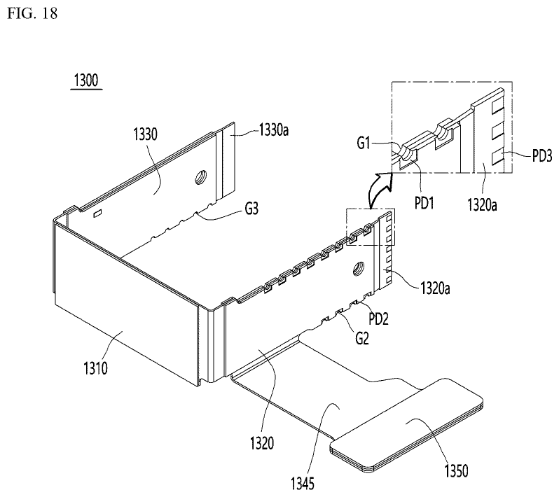

As shown in FIG. 17a, FIG. 18, FIG. 19, FIG. 23, and FIG. 24, a plurality of first bonding portions 11 are bonded to each of the first bonding pads PD11 and the first pads PD1 through the first bonding grooves G1, and may electrically connect the upper portion of the third board 1271 and the upper portion of the first circuit board portion 1320. A plurality of second bonding portions 12 are bonded to each of the second bonding pads PD12 and the second pads PD2 through the second bonding grooves G2, and can electrically connect the lower part of the third board 1271 and the lower part of the first circuit board portion 1320. In addition, the third board 1271 and the first circuit board portion 1320 can be electrically connected to the second sub-board 1273. Here, the number of the first bonding pads PD11 may be greater than the number of the second bonding pads PD12. Similarly, the number of the first pads PD1 may be greater than the number of the second pads PD2. In addition, the number of the first bonding grooves G1 may be greater than the number of the second bonding grooves G2.

A first flexible board 1320a may be extended to one side of the first circuit board portion 1320 or an area adjacent to the first board 1154a. The first flexible board 1320a has a thickness thinner than the thickness of the center area of the first circuit board portion 1320 and may be formed as an FPCB. The first flexible board 1320a has a degree of freedom in a direction perpendicular to the optical axis on one side of the first circuit board portion 1320, so that it may be in close contact with the other end of the first board 1154a. The first flexible board 1320a has a structure in which there is no resin board or reinforcing board on the outer or inner side.

A plurality of third pads PD3 are arranged in a vertical direction at one end of the first circuit board portion 1320 or one end of the first flexible board 1320a, and the third pad PD3 is an area where at least an outer layer of the first flexible board 1320a is open. A plurality of fourth pads PD4 are arranged in a vertical direction at the other end of the first board 1154a, and the fourth pad PD4 is an area where at least an outer layer of the first board 1154a is open. Each of the plurality of third pads PD3 and the plurality of fourth pads PD4 may be arranged correspondingly or adjacently in a horizontal direction. Here, the arrangement direction of the first pads may be perpendicular to the arrangement direction of the third pads.

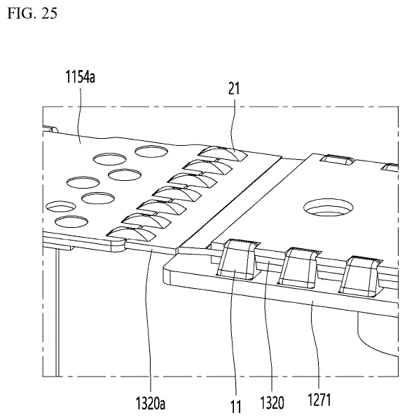

As shown in FIG. 19 and FIG. 25, the third bonding portion 21 is joined to the plurality of third pads PD3 and the plurality of fourth pads PD4, and can electrically connect the first circuit board portion 1320 and the first board 1154a of the first board portion 1154. Accordingly, the first circuit board portion 1320 and the first board 1154a of the first board portion 1154 can communicate with each other. For example, by connecting the first circuit board portion 1320 and the first board 1154a of the first board portion 1154, the driver portion 1390 can control the driving of at least two of the first and third coils through the first circuit board portion 1320 and the first board 1154a of the first board portion 1154. In addition, by connecting the first circuit board portion 1320 and the first board 1154a of the first board portion 1154, the current of the set coil in the first lens assembly 1100 can be controlled and data detected through the hall sensors 1153 can be received.

As shown in FIG. 17b, FIG. 20, FIG. 23, and FIG. 24, the other end of the second board 1154b of the first board portion 1154 and one end of the second circuit board portion 1330 of the circuit board 1300 may correspond to or face each other. Here, the other end of the second board 1154b is closer to the sensor side than the object side, and one end of the second circuit board portion 1330 is closer to the object side than the sensor side. A plurality of third bonding pads PD13 are exposed on the lower outer side of the fourth board 1272 of the second board portion 1270, and the plurality of third bonding pads PD13 may be arranged in the optical axis direction. The exposure of the third bonding pads PD13 is an area where at least the outer layer of the fourth board 1272 is open.

A plurality of fifth pads PD5 are arranged on the lower outer side of the second circuit board portion 1330, and can be arranged at positions corresponding to each of the plurality of third bonding pads PD13. The exposed portion of the fifth pad PD5 is an area where at least the outer layer of the second circuit board portion 1330 is open. Here, the lower portion of the fourth board 1272 and the lower portion of the second circuit board portion 1330 are areas adjacent to the inside of a portable terminal or a mobile device. A plurality of third bonding grooves G3 are arranged on the lower portion of the second circuit board portion 1330, and the third bonding grooves G3 can be concave from the lower portion of the second circuit board portion 1330 to the upper portion. The third bonding grooves G3 and the third bonding pads PD13 can correspond to each other or overlap in a horizontal direction (i.e., a direction orthogonal to the optical axis).

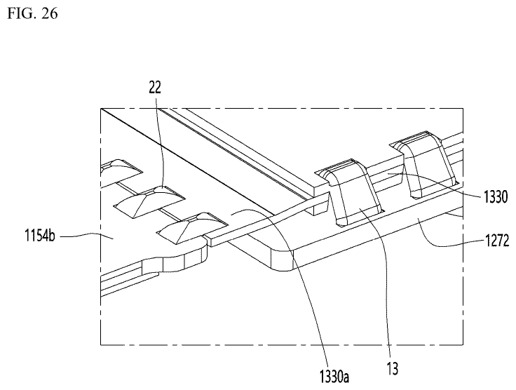

As shown in FIG. 20 and FIG. 26, a plurality of fourth bonding portions 13 are bonded to each of the third bonding pad PD13 and the fifth pad PD5 through the third bonding groove G3, and can electrically connect the lower part of the fourth board 1272 and the lower part of the second circuit board portion 1330. Here, the number of the fifth pads PD5 may be the same as the number of the third bonding grooves G3. The number of the third bonding pads PD13 may be smaller than the number of the first bonding pads PD11.

A second flexible board 1330a may extend to one side of the second circuit board portion 1330 or an area adjacent to the second board 1154b. The second flexible board 1330a is a region having a thickness thinner than the thickness of the center region of the second circuit board portion 1330, and may be formed as an FPCB. The second flexible board 1330a has a degree of freedom in a direction perpendicular to the optical axis on one side of the second circuit board portion 1330, so that it may be in close contact with the other end of the second board 1154b. The outer or inner side of the second flexible board 1330a has a structure in which there is no resin board or reinforcing board. A plurality of sixth pads PD6 are arranged in a vertical direction on one end of the second circuit board portion 1330 or one end of the second flexible board 1330a, and the sixth pad PD6 is a region in which at least the outer layer of the second flexible board 1330a is open. The arrangement direction of the fifth pad may be perpendicular to the arrangement direction of the sixth pad.

On the other end of the second board 1154b, a plurality of seventh pads PD7 are arranged in a vertical direction, and the seventh pads PD7 are areas where at least the outer layer of the second board 1154b is open. Each of the plurality of sixth pads PD6 and the plurality of seventh pads PD7 may be arranged to correspond to or be adjacent to each other in a horizontal direction.

The fifth bonding portion 22 is joined to each of the plurality of sixth pads PD6 and the plurality of seventh pads PD7, and may electrically connect the second circuit board portion 1330 and the second board 1154b of the first board portion 1154. Accordingly, the second circuit board portion 1330 and the second board 1154b of the first board portion 1154 may communicate with each other. For example, by connecting the second circuit board portion 1330 and the second board 1154b of the first board portion 1154, the driver portion 1390 can control the driving of at least two of the second and third coils through the second circuit board portion 1330 and the second board 1154b of the first board portion 1154. In addition, by electrically connecting the second circuit board portion 1330 and the second board 1154b of the first board portion 1154, the current of the coil set in the first lens assembly 1100 can be controlled, and data detected through the hall sensors 1153 can be received.

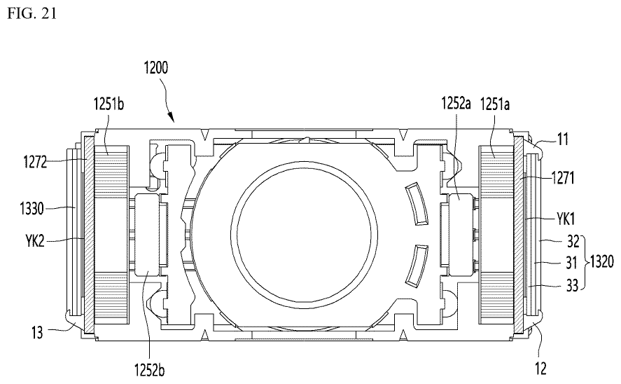

As shown in FIG. 21, the first and second circuit board portions 1320, 1330 include a flexible board layer 31, and the inner layer 32 and the outer layer 33 of the flexible board layer 31 may include a circuit pattern board or/and a reinforcing board. The circuit board 1300 may include a circuit board having a wiring pattern that can be electrically connected, such as a rigid printed circuit board (Rigid PCB), a flexible printed circuit board (Flexible PCB), or a rigid flexible printed circuit board (Rigid Flexible PCB). The circuit board 1300 may be electrically connected to another camera module in the terminal or a processor of the terminal. Through this, the lens assembly described above and the camera device including the same may transmit and receive various signals in the terminal.

As in (a)(b) of FIG. 22, the third bonding portion 21 and the fifth bonding portion 22 may be respectively positioned on both sides between the first and second lens assemblies 1100, 1200. The third bonding portion 21 may be positioned further toward the object than one end of the third board 1271. The fifth bonding portion 22 may be positioned further toward the object than one end of the fourth board 1272. The thickness of the other end of the first board 1154a may be thicker than the thickness of the first flexible board 1320a or the thickness of one end of the first circuit board portion 1320. The thickness of the other end of the second board 1154b may be thicker than the thickness of the second flexible board 1330a or the thickness of one end of the second circuit board portion 1330. The above first and second flexible boards 1320a, 1330a can extend obliquely in a direction close to the optical axis from the thick region of the first and second circuit board portions 1320, 1330.

The driver portion 1390 is mounted on the inner side of the third board 1271 of the second board portion 1270 and can be electrically connected to the third board 1271 and the fourth board 1272. The driver portion 1390 can communicate with at least one of the fourth and fifth coils 1251a, 1251b connected to the second board portion 1270 using at least two channels and can receive sensing data detected through the Hall sensor 1253a and 1253b. The above driver portion 1390 can communicate with the first, second, and third coils 1152a and 1152b and 1152c connected to the first board portion 1154 by using at least two channels through the connection of the second board portion 1270, the circuit board 1300, and the first board portion 1154, and can receive sensing data detected through the hall sensor 1153a and 1153b. Therefore, the driver portion 1390 can perform driving control of the first lens assembly 1100 and driving control of the second lens assembly 1200 through at least four channels.

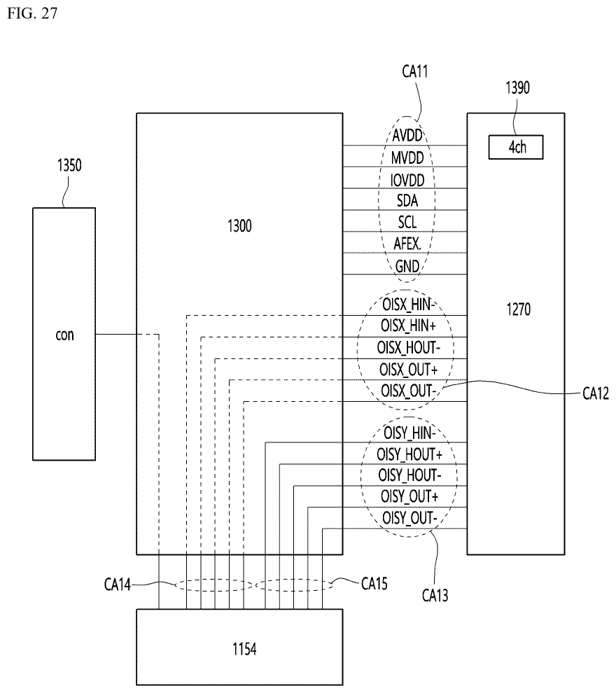

Referring to FIG. 27, the connector board 1350 is electrically connected to the circuit board 1300, and the circuit board 1300 and the second board portion 1270 can be connected to pins or terminals, such as various voltages (AVDD, MVDD, IOVDD), serial clock (SCL), serial data (SDA), gyro sensor data (AFEX), and ground (GND), through the first interface CA11. The circuit board 1300 and the second board portion 1270 can be connected to pins or terminals, such as input/output signals (OISX_HIN−, OISX_HOUT+, OISX_OUT+, OISX_OUT−) for X-axis tilt for OIS, through the second interface CA12. The circuit board 1300 and the second board portion 1270 can be connected to pins or terminals such as input/output signals (OISY_HIN−, OISY_HOUT+, OISY_OUT+, OISY_OUT−) for Y-axis tilt for OIS through the third interface CA13.

The second board portion 1270 can be connected to the first board portion 1154 through the fourth interface CA14 and the fifth interface CA15 through the circuit board 1300. The fourth interface CA14 can transmit signals of the second interface CA12. The fifth interface CA15 can transmit signals of the third interface CA13. That is, the control signals for OIS of the second board portion 127 can be transmitted through the circuit board 1300. It can be transmitted to the first board portion 1154 through the circuit board 1300. This can be transmitted to the first board portion 1154 through the circuit board 1300 by having at least 4 channels (ch) of driver portion 1390 in the second board portion 1270, and a separate driver IC is not mounted in the first board portion 1154. In addition, the first to fifth bonding portions are made of solder material, and the total number of bonding portions can be 20 or more or 25 or more. Therefore, the zoom function and the OIS function can be controlled simultaneously using at least 4 channels of driver portion 1390, so that the manufacturing cost of the camera module can be reduced, and the driving control for the zoom function and the OIS function can be facilitated.

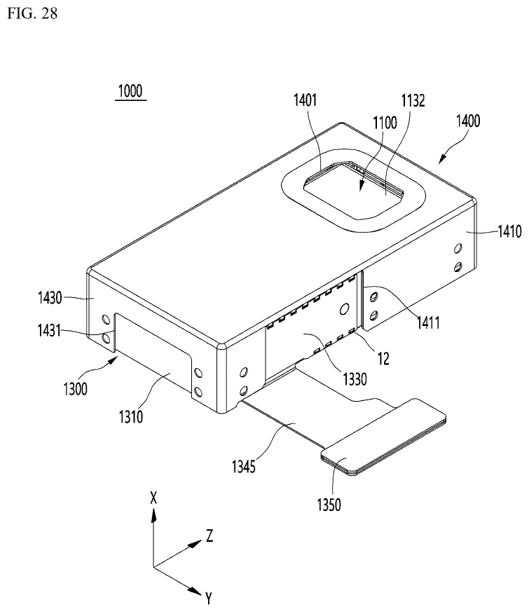

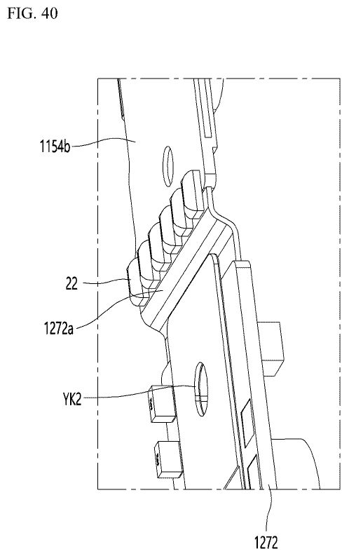

The camera module according to the second embodiment will be described with reference to FIGS. 28, 29, 30 to 41. The description of the second embodiment refers to the description of the first embodiment for the same configuration as the first embodiment, and may include the description of the first embodiment disclosed in FIGS. 5 to 15 for the first and second lens assemblies.

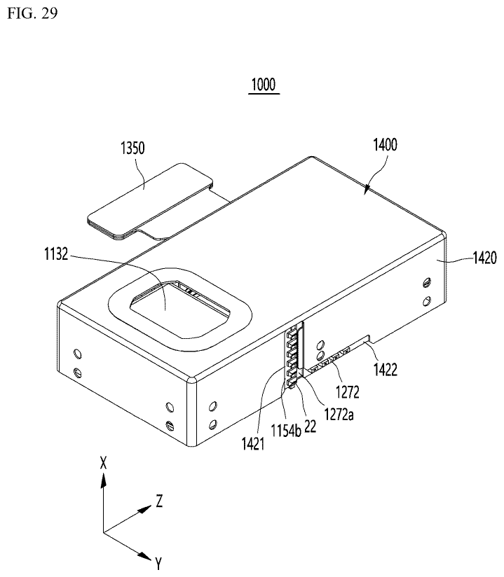

As shown in FIGS. 28 and 29, the housing 1400 has a first open region 1411 on the first side 1410, and the first open region 1411 may expose a part of the first side of the first and second lens assemblies 1100, 1200. The housing 1400 has second and third open regions 1421, 1423 on the second side 1420, and the second and third open regions 1421 and 1422 may expose a part of the second side of the first and second lens assemblies 1100, 1200. The second and third open regions 1421 and 1422 may overlap the first open region 1411 in the horizontal direction (Y) and may be connected to each other. The sum of the areas of the second and third open regions 1421 and 1422 on each side of the housing 1400 may be smaller than the area of the first open region 1411. The housing 1400 may have a fourth open region 1431 on the sensor side 1430, and a shield can (not shown) connected to the circuit board 1300 may be placed on the fourth open region 1431.

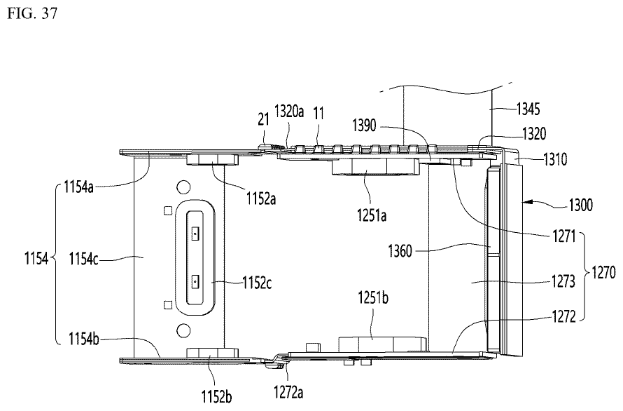

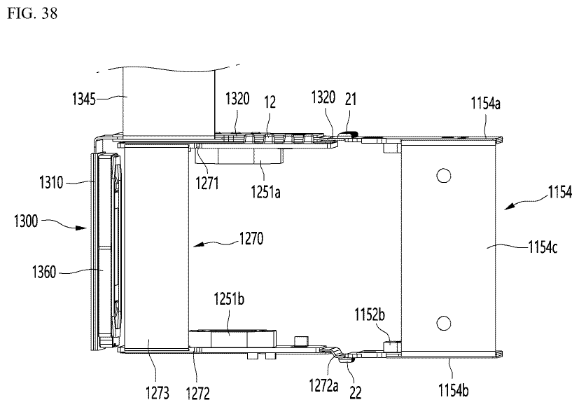

The first lens assembly 1100 may include a first board portion 1154. The first board portion 1154 may include a first board 1154a disposed on a first side or one side of the first lens assembly 1100 and a second board 1154b disposed on a second side or the other side. Each of the first board 1154a and the second board 1154b may have a multi-layer structure and may include a reinforcing plate on an outer side. The first board 1154a and the second board 1154b may have a multi-layer structure and may include a reinforcing plate on an outer side. The first board 1154a and the second board 1154b may be disposed on opposite sides of each other and may be electrically connected to each other. The first board 1154a and the second board 1154b may be connected by a first sub-board 1154c, as shown in FIG. 9, FIG. 37, and FIG. 38. The first sub-board 1154c may be a flexible board. The first board 1154a and the second board 1154b may have a rigid board inside and may extend to the first sub-board 1154c.

The second lens assembly 1200 may include a second board portion 1270 on the outside, as shown in FIG. 37 and FIG. 38. The second board portion 1270 may include a third board 1271 arranged on the first side or one side of the second lens assembly 1200 and a fourth board 1272 arranged on the second side or the other side. Each of the third board 1271 and the fourth board 1272 may have a multi-layer structure and may include a reinforcing plate on the outside.

The third board 1271 and the fourth board 1271 may be arranged on opposite sides and may be electrically connected to each other. The third board 1271 and the fourth board 1272 may be connected by the second sub-board 1273, as shown in FIG. 37 and FIG. 38. The second sub-board 1273 may be a flexible board. The third board 1271 and the fourth board 1272 may have rigid boards inside and may extend to the second sub-board 1273.

The second board portion 1270 may include a driver portion 1390 on the inside. The driver portion 1390 supplies a signal for controlling the driving of the first and second lens assemblies 1100, 1200. The driver portion 1390 may be implemented as a chip that can communicate with three or more channels, for example, at least four channels, as a driver IC. The above driver portion 1390 is located on the inner side of the third board 1271 or the fourth board 1272, and may be preferably arranged on the inner side of the third board 1271 adjacent to the connector board 1350. The first board portion 1154 may be provided without the driver portion, and may be provided without the driver portion on the inner side of the first or second board 1154a, 1154b, for example.

The driver portion 1390 may communicate with two channels out of four channels to control the driving of the optical member 1132 of the first lens assembly 1100 through the first board portion 1154, and may communicate with two channels to control the driving of the lenses of the second lens assembly 1200 of the second board portion 1270.

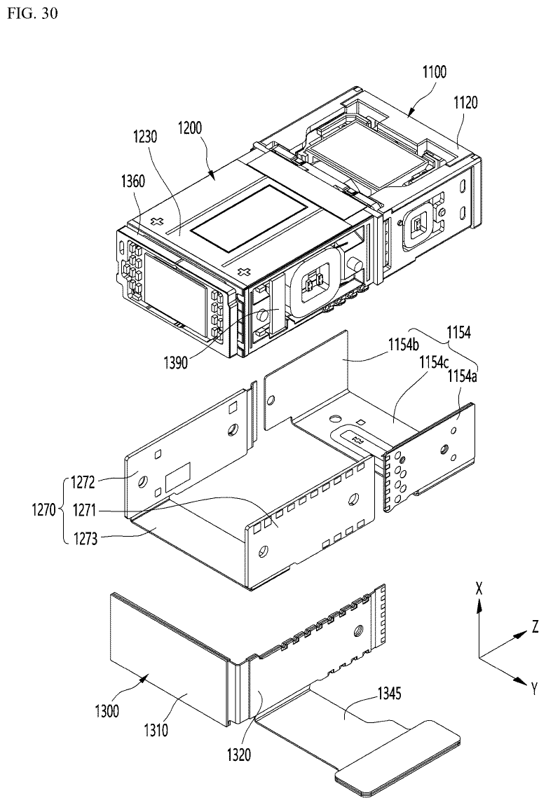

Referring to FIGS. 30 to 38, a circuit board 1300 according to the second embodiment may include a sensor board portion 1310 on which an image sensor (IS) is arranged, and a first circuit board portion 1320 bent from one end of the sensor board portion 1310 toward the first board 1154a. An image sensor (IS) may be mounted on an inner surface of the sensor board portion 1310 and may be electrically connected to the image sensor (IS). The above sensor board portion 1310 is located at the rear end of the second lens assembly 12000, and at least one optical filter (e.g., infrared, etc.) can be arranged on the image sensor (IS). Here, the circuit board 1300 is used interchangeably with the main board described below.

In addition, the first circuit board portion 1320 can be located at the first side of the second lens assembly 1200 or the second carrier 1230. In particular, the first circuit board portion 1320 is adjacent to the fourth coil 1251a located adjacent to the first side, and can be easily electrically connected to the third board 1171.

The second board portion 1170 includes the third board 1171 and the fourth board 1272, and the third board 1171 and the fourth board 1272 The circuit board 1300 is electrically connected to the second sub-board 1173. The second sub-board 1173 of the second board portion 1170 may be located at the bottom of the second lens assembly 1200. The third board 1171 may be located between the second carrier 1230 and the first circuit board portion 1320, and the fourth board 1272 may be located on the outside of the second carrier 1230.

The first board 1154a and the second board 1154b of the first board portion 1154 are located on both sides of the first carrier 1120, and the first sub-board 1154c may be located at the bottom of the first carrier 1120. The first board 1154a is located on the object side of the first circuit board portion 1320 and can be electrically connected to the first circuit board portion 1320. The first board 1154a can be electrically connected to the second board portion 1270 through the first circuit board portion 1320. The second board 1154b is located on the object side of the fourth board 1272 and can be electrically connected to the second board portion 1270. The second board 1154b can be electrically connected to the circuit board 1300 through the second board portion 1270. The first board 1154a and the second board 1154b of the first board portion 1154 can be electrically connected by the first sub-board 1154c.

The second embodiment of the invention may include a driver portion 1390 as a single driver IC to control the driving of the first and second lens assemblies 1100, 1200. The driver portion 1390 may be placed on the inner side of the third board 1371 of the second board 1370 and may be accommodated in the receiving groove (1279, FIG. 14) of the first side of the second carrier 1230. As another example, the driver portion 1390 may be placed on the fourth board 1272.

Since the driver portion 1390 is placed on the second board 1270, electrical connection with the circuit board 1300, which is the main board, may be facilitated, and the communication path with the circuit board 1300 may be reduced. In addition, since the driver portion 1390 is mounted on the inside of the first circuit board portion 1320 from which the connector board 1350 extends or on the inside of the third board 1271 adjacent to the first circuit board portion 1320, the communication path with the connector board 1350 can be reduced.

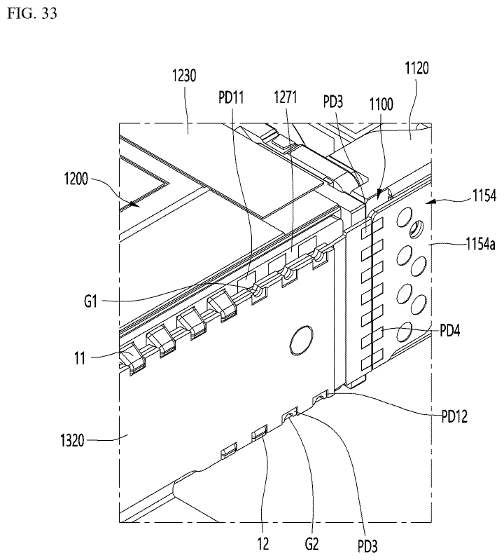

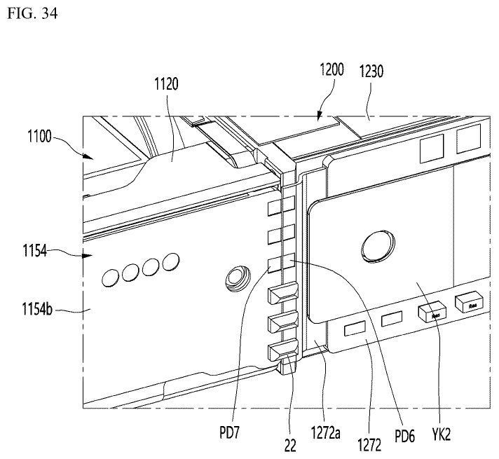

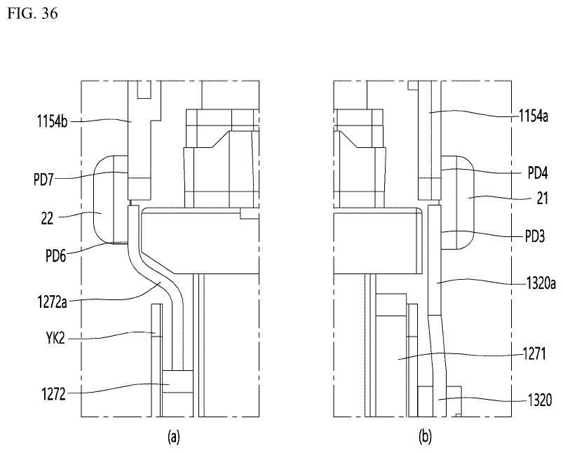

As shown in FIG. 33, FIG. 34, and FIG. 36, the other end of the first board 1154a of the first board portion 1154 and one end of the first circuit board portion 1320 of the circuit board 1300 can correspond to or face each other. Here, the other end of the first board 1154a is closer to the sensor side than the object side, and one end of the first circuit board portion 1320 is closer to the object side than the sensor side. On the upper and lower outer sides of the third board 1271 of the second board portion 1270, a plurality of first and second bonding pads (PD11, PD12) are exposed, and the plurality of first and second bonding pads (PD11, PD12) can be arranged in the optical axis direction. The exposure of the first and second bonding pads (PD11, PD12) is an area where the outer layer of the third board 1271 is opened. Here, the optical axis direction can be a direction from the object side toward the sensor side or a direction parallel to the optical axis.

On the upper outer side of the first circuit board portion 1320, a plurality of first pads PDI are arranged, and can be arranged at positions corresponding to each of the plurality of first bonding pads PD11. A plurality of second pads PD2 are arranged on the lower outer side of the first circuit board portion 1320, and can be arranged at positions corresponding to each of the plurality of second bonding pads PD12. The exposed portions of the first and second pads (PD1, PD2) are areas where at least the outer layer of the first circuit board portion 1320 is open. Here, the upper portion of the third board 1271 and the upper portion of the first circuit board portion 1320 are areas adjacent to the outer cover of the mobile terminal or the outer side of the moving body. The upper portion of the third board 1271 and the lower portion of the first circuit board portion 1320 are located in opposite directions to the upper portion of the third board 1271 and the upper portion of the first circuit board portion 1320.

As shown in FIG. 33, a plurality of first and second bonding grooves G1 and G2 are arranged on the upper and lower portions of the first circuit board portion 1320. The first bonding groove G1 may be concave from the upper portion to the lower portion of the first circuit board portion 1320, and the second bonding groove G2 may be concave from the lower portion to the upper portion of the first circuit board portion 1320. The shape of each of the first and second bonding grooves G1 and G2 may be a hemispherical shape or a polygonal shape. The first bonding groove G1 and the first bonding pad PD1 may correspond to each other or overlap in a horizontal direction (i.e., a direction orthogonal to the optical axis). The second bonding groove G2 and the second bonding pad PD12 may correspond to each other or overlap in a horizontal direction (i.e., a direction orthogonal to the optical axis).

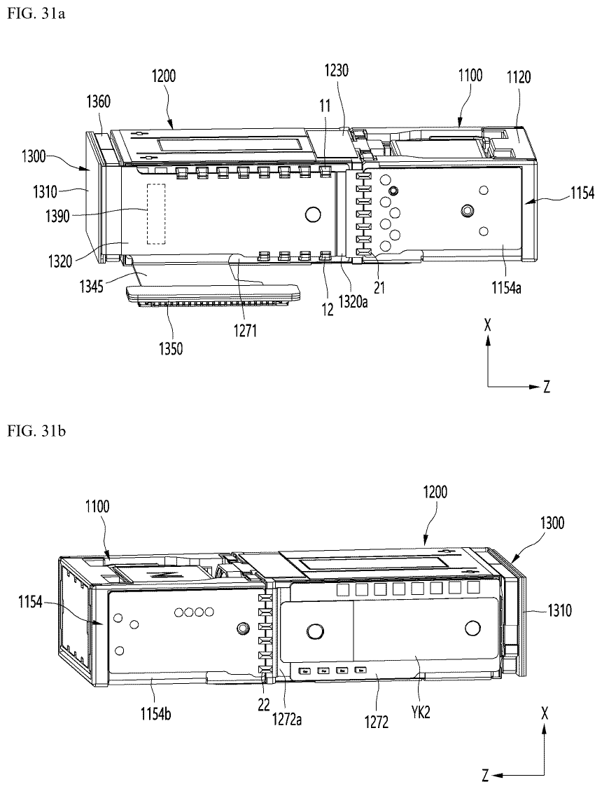

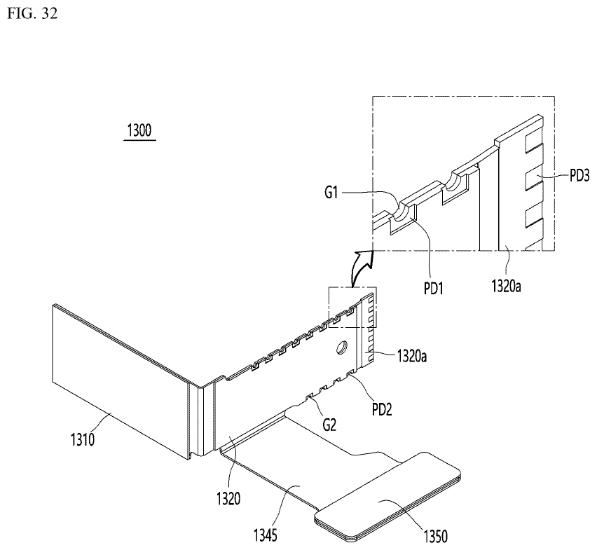

As shown in FIG. 31a, FIG. 32, FIG. 33, FIG. 37, and FIG. 38, a plurality of first bonding portions 11 are bonded to the first bonding pad PD11 and the first pad PD1 through the first bonding groove G1, respectively, and can electrically connect the upper part of the third board 1271 and the upper part of the first circuit board portion 1320. A plurality of second bonding portions 12 are bonded to the second bonding pad PD12 and the second pad PD2 through the second bonding groove G2, respectively, and can electrically connect the lower part of the third board 1271 and the lower part of the first circuit board portion 1320. In addition, the third board 1271 and the first circuit board portion 1320 can be electrically connected to the second sub-board 1273. Here, the number of the first bonding pads PD11 may be greater than the number of the second bonding pads PD12. Similarly, the number of the first pads PD1 may be greater than the number of the second pads PD2. In addition, the number of the first bonding grooves G1 may be greater than the number of the second bonding grooves G2.

A first flexible board 1320a may be extended to one side of the first circuit board portion 1320 or an area adjacent to the first board 1154a. The first flexible board 1320a is an area having a thickness thinner than the thickness of the center area of the first circuit board portion 1320 and may be formed of an FPCB. The first flexible board 1320a has a degree of freedom in a direction perpendicular to the optical axis on one side of the first circuit board portion 1320, so that it can be in close contact with the other end of the first board 1154a. The first flexible board 1320a has a structure in which there is no resin board or reinforcing board on the outer or inner side.

A plurality of third pads PD3 are arranged in a vertical direction on one end of the first circuit board portion 1320 or one end of the first flexible board 1320a, and the third pads PD3 are regions in which at least the outer layer of the first flexible board 1320a is open. A plurality of fourth pads PD4 are arranged in a vertical direction on the other end of the first board 1154a, and the fourth pads PD4 are regions in which at least the outer layer of the first board 1154a is open. Each of the plurality of third pads PD3 and the plurality of fourth pads PD4 may be arranged to correspond to or be adjacent to each other in a horizontal direction. Here, the arrangement direction of the first pad may be perpendicular to the arrangement direction of the third pad.

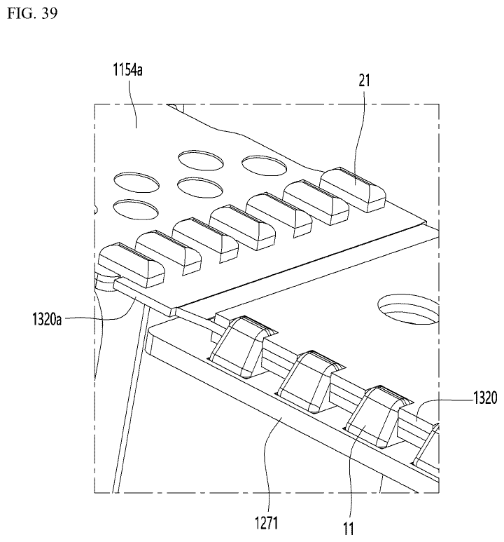

As shown in FIG. 33 and FIG. 39, the third bonding portion 21 is joined to the plurality of third pads PD3 and the plurality of fourth pads PD4, and may electrically connect the first circuit board portion 1320 and the first board 1154a of the first board portion 1154. Accordingly, the first circuit board portion 1320 and the first board 1154a of the first board portion 1154 may communicate with each other. For example, by connecting the first circuit board portion 1320 and the first board 1154a of the first board portion 1154, the driver portion 1390 can control the driving of at least two of the first and third coils through the first circuit board portion 1320 and the first board 1154a of the first board portion 1154. In addition, by connecting the first circuit board portion 1320 and the first board 1154a of the first board portion 1154, the current of the set coil in the first lens assembly 1100 can be controlled and data detected through the hall sensors 1153 can be received.

As shown in FIG. 31b, FIG. 34, FIG. 37 and FIG. 38, the other end of the second board 1154b of the first board portion 1154 and one end of the fourth board 1272 of the second board portion 1270 may correspond to or face each other. Here, the other end of the second board 1154b is closer to the sensor side than the object side, and one end of the fourth board 1272 is closer to the object side than the sensor side. A plurality of third bonding pads (not shown) are exposed on the lower outer side of the fourth board 1272 of the second board portion 1270, and the plurality of third bonding pads may be arranged in the optical axis direction. The exposure of the third bonding pad is an area where at least the outer layer of the fourth board 1272 is open.

A second flexible board 1272a may be extended to one side of the fourth board 1272 or an area adjacent to the second board 1154b. The second flexible board 1272a has a thickness thinner than the thickness of the center area of the fourth board 1272 and may be formed as an FPCB. The second flexible board 1272a may be in close contact with the other end of the second board 1154b by having a degree of freedom in a direction perpendicular to the optical axis on one side of the fourth board 1272. The second flexible board 1272a has a structure in which there is no resin board or reinforcing board on the outer or inner side. A plurality of sixth pads PD6 are arranged in a vertical direction at one end of the fourth board 1272 or one end of the second flexible board 1272a, and the sixth pad PD6 is an area where at least the outer layer of the second flexible board 1272a is open. The arrangement direction of the sixth pad PD6 may be perpendicular to the optical axis.

A plurality of seventh pads PD7 are arranged in a vertical direction at the other end of the second board 1154b, and the seventh pad PD7 is an area where at least the outer layer of the second board 1154b is open. Each of the plurality of sixth pads PD6 and the plurality of seventh pads PD7 may correspond to or be arranged adjacent to each other in a horizontal direction.

The fourth bonding portion 22 is joined to each of the plurality of sixth pads PD6 and the plurality of seventh pads PD7, and can electrically connect the fourth board 1272 and the second board 1154b of the first board portion 1154. Accordingly, the fourth board 1272 and the second board 1154b of the first board portion 1154 can communicate with each other. For example, by connecting the fourth board 1272 and the second board 1154b of the first board portion 1154, the driver portion 1390 can control the driving of at least two of the second and third coils through the fourth board 1272 and the second board 1154b of the first board portion 1154. In addition, since the fourth board 1272 and the second board 1154b of the first board portion 1154 are electrically connected, the current of the coil set in the first lens assembly 1100 can be controlled, and data detected through the hall sensors 1153 can be received.

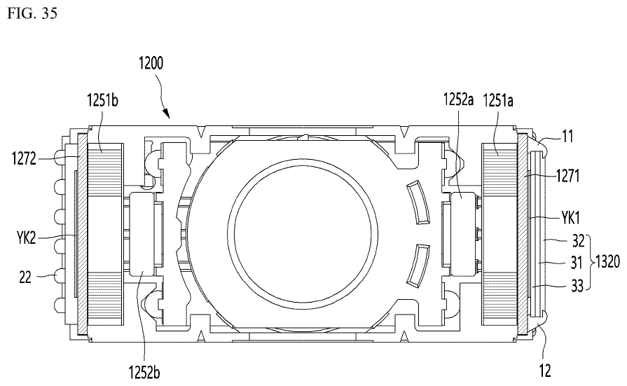

As shown in FIG. 35, the first circuit board portion 1320 includes a flexible board layer 31, and the inner layer 32 or/and the outer layer 33 of the flexible board layer 31 can include a circuit pattern board or/and a reinforcing board. This circuit board 1300 can include a circuit board having a wiring pattern that can be electrically connected, such as a rigid printed circuit board (Rigid PCB), a flexible printed circuit board (Flexible PCB), or a rigid flexible printed circuit board (Rigid Flexible PCB). The circuit board 1300 may be electrically connected to another camera module or processor of the terminal within the terminal. Through this, the lens assembly and the camera device including the lens assembly described above may transmit and receive various signals within the terminal.

As shown in (a) and (b) of FIG. 36, the third bonding portion 21 and the fourth bonding portion 22 may be respectively arranged on both sides between the first and second lens assemblies 1100, 1200. The third bonding portion 21 may be arranged further toward the object than one end of the third board 1271. The fourth bonding portion 22 may be arranged further toward the object than one end of the fourth board 1272. The thickness of the other end of the first board 1154a may be thicker than the thickness of the first flexible board 1320a or the thickness of one end of the first circuit board portion 1320. The thickness of the other end of the second board 1154b may be thicker than the thickness of the second flexible board 1272a or the thickness of one end of the fourth board 1272. The first and second flexible boards 1320a, 1272a may extend in a direction close to the optical axis from the thick region of the first circuit board portion 1320 and the fourth board 1272 in a slanted or curved manner.

The driver portion 1390 may be mounted on the inner side of the third board 1271 of the second board portion 1270 and may be electrically connected to the third board 1271 and the fourth board 1272. The driver portion 1390 can communicate with at least one of the fourth and fifth coils 1251a, 1251b connected to the second board portion 1270 using at least two channels and can receive sensing data detected through the Hall sensor 1253a and 1253b. The driver portion 1390 can communicate with the first, second, and third coils 1152a and 1152b and 1152c connected to the first board portion 1154 using at least two channels by connection of the second board portion 1270, the circuit board 1300, and the first board portion 1154, and can receive sensing data detected through the Hall sensor 1153a and 1153b. Therefore, the driver portion 1390 can perform driving control of the first lens assembly 1100 and driving control of the second lens assembly 1200 through at least four channels.

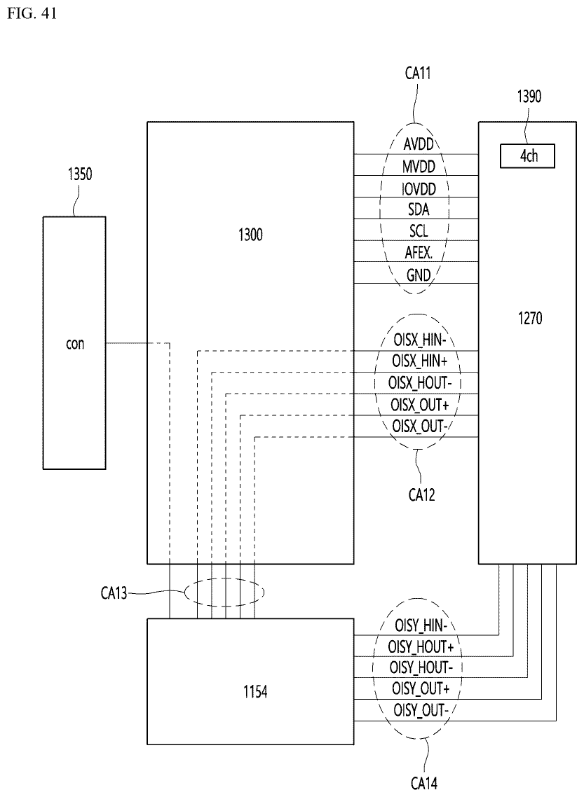

Referring to FIG. 41, the connector board 1350 is electrically connected to the circuit board 1300, and the circuit board 1300 and the second board portion 1270 can be connected to pins or terminals for signals such as various voltages (AVDD, MVDD, IOVDD), serial clock (SCL), serial data (SDA), gyro sensor data (AFEX), and ground (GND) through the first interface CA11. The circuit board 1300 and the second board portion 1270 can be connected to pins or terminals, such as input/output signals (OISX_HIN−, OISX_HOUT+, OISX_OUT+, OISX_OUT−) for X-axis tilt for OIS, through the second interface CA12.

The circuit board 1300 can be connected to the second board portion 1270 and the second interface CA12 through the third interface CA13, and the third interface CA13 can be connected to pins or terminals, such as input/output signals (OISX_HIN−, OISX_HOUT+, OISX_OUT+, OISX_OUT−) for X-axis tilt of the OIS function. The second board portion 1270 and the first board portion 1154 can be connected to pins or terminals such as input/output signals (OISY_HIN−, OISY_HOUT+, OISY_OUT+, OISY_OUT−) for Y-axis tilt of the OIS function through the fourth interface CA14.

The second board portion 1270 can be connected to the first board portion 1154 through the second interface CA12 and the third interface CA13 through the circuit board 1300. The third interface CA12 can transmit signals of the fourth interface CA12. In addition, since the second board portion 1270 is directly connected to the first board portion 1154 and the fourth interface CA13, signals other than signals of the second interface CA12 can be transmitted. That is, the first signals (i.e., X-axis tilt signals) for controlling the OIS of the second board portion 1270 are transmitted to the first board portion 1154 through the circuit board 1300, and the second signals (Y-axis tilt signals) for controlling the OIS can be directly transmitted to the first board portion 1154. The first and second signals can be distinguished as the X-axis tilt and Y-axis tilt of the OIS function. As another example, the second board portion 1270 can directly transmit the first signals to the first board portion 1154, and the second signals can be transmitted through the circuit board 1300.

Accordingly, at least 4 channels (ch) of driver portions 1390 are provided in the second board portion 1270, so that the signal can be transmitted to the first board portion 1154 through the circuit board 1300, and a separate driver IC is not mounted in the first board portion 1154. In addition, the first to fourth bonding portions may be made of solder material, and the total number of bonding portions may be 18 or more or 20 or more. Therefore, the zoom function and the OIS function can be simultaneously controlled using at least 4 channels of driver portions 1390, so that the manufacturing cost of the camera module can be reduced, and the drive control for the zoom function and the OIS function can be easily performed.

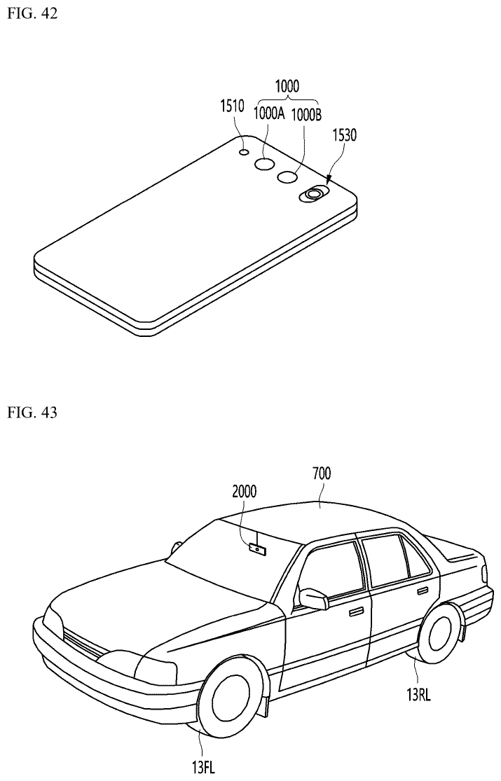

FIG. 42 is a perspective view of a mobile terminal to which a camera module according to an embodiment is applied.

As shown in FIG. 42, the mobile terminal 1500 of the embodiment may include a camera module 1000, a flash module 1530, and an autofocus device 1510 provided on the rear side. The camera module 1000 may include an image capturing function and an autofocus function. For example, the camera module 1000 may include an autofocus function using an image. The camera module 1000 processes an image frame of a still image or a moving image obtained by an image sensor in a shooting mode or a video call mode. The processed image frame may be displayed on a predetermined display portion and may be stored in a memory. A camera (not shown) may also be arranged on the front side of the mobile terminal body. For example, the camera module 1000 may include a first camera module 1000A and a second camera module 1000B, and OIS can be implemented with AF or zoom function by the first camera module 1000A. The flash module 1530 can include a light-emitting element that emits light inside. The flash module 1530 can be operated by the camera operation of the mobile terminal or the control of the user.

The autofocus device 1510 can include one of the packages of the surface light emitting laser element as a light-emitting portion. The autofocus device 1510 can include an autofocus function using a laser. The autofocus device 1510 can be mainly used in conditions where the autofocus function using the image of the camera module 1000 is degraded, such as a close range of 10 m or less or a dark environment. The autofocus device 1510 may include a light emitting portion including a vertical cavity surface emitting laser (VCSEL) semiconductor device and a light receiving portion that converts light energy into electrical energy, such as a photodiode.

FIG. 43 is a perspective view of a vehicle to which a camera module according to an embodiment is applied. FIG. 43 is an exterior view of a vehicle equipped with a vehicle driving assistance device to which a camera module 1000 according to an embodiment is applied.

Referring to FIG. 43, the vehicle 700 according to the embodiment may be equipped with wheels (13FL, 13FR) that rotate by a power source and a predetermined sensor. The sensor may be a camera sensor 2000, but is not limited thereto. The camera 2000 may be a camera sensor to which a camera module 1000 according to the embodiment is applied. The vehicle 700 according to the embodiment may obtain image information through a camera sensor 2000 that captures a front image or a surrounding image, and may determine a lane non-identification situation using the image information and generate a virtual lane when the lane is not identified. For example, the camera sensor 2000 can capture the front of the vehicle 700 to obtain a front image, and the processor (not shown) can analyze an object included in the front image to obtain image information.

If an object such as a center divider, curb, or street tree corresponding to a lane, an adjacent vehicle, an obstacle, or an indirect road sign is captured in the image captured by the camera sensor 2000, the processor can detect the object and include it in the image information. At this time, the processor can obtain distance information to the object detected through the camera sensor 2000 to further supplement the image information. The image information can be information about the object captured in the image. The camera sensor 2000 can include an image sensor and an image processing module.

The camera sensor 2000 can process a still image or a moving image obtained by an image sensor (for example, a CMOS or CCD). The image processing module can process still images or moving images acquired through the image sensor, extract necessary information, and transmit the extracted information to the processor. At this time, the camera sensor 2000 can include a stereo camera to improve the measurement accuracy of the object and secure more information such as the distance between the vehicle 700 and the object, but is not limited thereto.

Although the above has been described with reference to the embodiments, these are merely examples and do not limit the present invention, and those skilled in the art will understand that various modifications and applications not exemplified above are possible without departing from the essential characteristics of the present invention. For example, each component specifically shown in the embodiments can be modified and implemented. And differences related to such modifications and applications should be interpreted as being included in the scope of the present invention defined in the appended claims.

1-15. (canceled)

16. A camera module comprising:
a first lens assembly having an optical member that reflects incident light toward an image sensor, and a first driving portion that controls a tilt of the optical member;
a plurality of lens holders arranged on a sensor side of the first lens assembly and having at least one lens;
a second lens assembly including a second driving portion that controls movement in an optical axis direction for at least one of the plurality of lens holders;
a first board having a first board portion arranged on a first side of the first lens assembly and a second board arranged on a second side opposite to the first side of the first lens assembly;
a second board portion having a third board arranged on a first side of the second lens assembly and a fourth board arranged on a second side of the second lens assembly;
a circuit board including a sensor board portion having the image sensor arranged on an inside, and a first circuit board portion extending from the sensor board portion to an outside of the third board; and
a driver portion arranged on an inside of the third board of the second board portion, and electrically connected to the first board portion, the second board portion, and the circuit board,
wherein the driver portion is electrically connected to the first board portion through the first circuit board portion and the fourth board.

17. The camera module of claim 16, wherein the first board portion is arranged on a bottom of the first lens assembly, and includes a first sub-board connected to the first board and the second board, and
wherein the second board portion is arranged on a bottom of the second lens assembly, and includes a second sub-board connected to the third board and the fourth board.

18. The camera module of claim 16, comprising:
a plurality of first bonding pads on an upper side of the third board and a plurality of first pads on an upper side of the first circuit board portion;
a plurality of second bonding pads on a lower side of the third board and a plurality of second pads on a lower side of the first circuit board portion;
a plurality of first bonding portions bonded the plurality of first bonding pads and the plurality of first pads to each other, respectively; and
a plurality of second bonding portions bonded the plurality of second bonding pads and the plurality of second bonding pads to each other, respectively.

19. The camera module of claim 18, wherein the number of the first pads is greater than the number of the second pads.

20. The camera module of claim 18, wherein the plurality of first bonding pads, the plurality of first pads, the plurality of second bonding pads, and the plurality of second pads are arranged in the optical axis direction.

21. The camera module of claim 18, wherein the first circuit board portion has a plurality of first bonding grooves on each of the plurality of first pads, and
wherein the plurality of first bonding portions is bonded to the first bonding pad and the first pad through the plurality of first bonding grooves.

22. The camera module of claim 21, wherein the second circuit board portion has a plurality of second bonding grooves below each of the plurality of second pads, and
wherein the plurality of second bonding portions is bonded to the second bonding pad and the second pad through the plurality of second bonding grooves.

23. The camera module of claim 18, wherein the other end of the first board and one end of the first circuit board portion have a plurality of pads and are adjacent to each other and are electrically connected by a plurality of third bonding portions, and
wherein the other end of the second board and one end of the fourth board have a plurality of pads and are adjacent to each other and are electrically connected by a plurality of fourth bonding portions.

24. The camera module of claim 23, wherein a plurality of third pads is arranged in a vertical direction at one end of the first circuit board portion, and
wherein the plurality of pads arranged at the other end of the first board and the plurality of pads at one end of the fourth board are arranged perpendicular to the optical axis direction.

25. The camera module of claim 18, wherein the circuit board includes a connector board extending outwardly from the first circuit board portion adjacent to the driver portion.

26. A camera module comprising:
a first lens assembly having an optical member that reflects incident light toward an image sensor, and a first driving portion that controls a tilt of the optical member;
a plurality of lens holders arranged on a sensor side of the first lens assembly and having at least one lens;
a second lens assembly including a second driving portion that controls movement in an optical axis direction for at least one of the plurality of lens holders;
a first board having a first board portion arranged on a first side of the first lens assembly and a second board arranged on a second side opposite to the first side of the first lens assembly;
a second board portion having a third board arranged on a first side of the second lens assembly and a fourth board arranged on a second side of the second lens assembly;
a circuit board including a sensor board portion having the image sensor arranged on an inside, a first circuit board portion extending from the sensor board portion to an outside of the third board, and a second circuit board portion extending outward from the sensor board portion to an outside of the fourth board, and
a driver portion arranged on an inside of the third board of the second board portion, and electrically connected to the first board portion, the second board portion, and the circuit board,
wherein the driver portion is electrically connected to the first board portion through the circuit board.

27. The camera module of claim 26, wherein the first board portion is arranged on a bottom of the first lens assembly, and includes a first sub-board connected to the first board and the second board, and
wherein the second board portion is arranged on a bottom of the second lens assembly, and includes a second sub-board connected to the third board and the fourth board.

28. The camera module of claim 26, comprising:
a plurality of first bonding pads on an upper side of the third board and a plurality of first pads on an upper side of the first circuit board portion;
a plurality of second bonding pads on a lower side of the third board and a plurality of second pads on a lower side of the first circuit board portion;
a plurality of first bonding portions bonded the plurality of first bonding pads and the plurality of first pads to each other, respectively; and
a plurality of second bonding portions bonded the plurality of second bonding pads and the plurality of second bonding pads to each other, respectively,
wherein the number of the first pads is greater than the number of the second pads.

29. The camera module of claim 27, wherein the plurality of first bonding pads, the plurality of first pads, the plurality of second bonding pads, and the plurality of second pads are arranged in the optical axis direction.

30. The camera module of claim 27, wherein the first circuit board portion has a plurality of first bonding grooves on each of the plurality of first pads, and the plurality of first bonding portions is bonded to the first bonding pad and the first pad through the plurality of first bonding grooves, and
wherein the second circuit board portion has a plurality of second bonding grooves below each of the plurality of second pads, and the plurality of second bonding portions is bonded to the second bonding pad and the second pad through the plurality of second bonding grooves.

31. The camera module of claim 26, comprising:
a plurality of pads disposed on the other end of the first board and one end of the first circuit board; and
a plurality of third bonding portion bonded to the plurality of pads disposed on the other end of the first board and one end of the first circuit board.

32. The camera module of claim 26, comprising:
a plurality of third bonding pads disposed on the lower portion of the fourth board, and a plurality of fifth pads disposed on a lower portion of the second circuit board,
wherein the second circuit board includes a plurality of third bonding grooves recessed beneath each of the plurality of fifth pads disposed on the lower portion of the second circuit board, and
wherein the second circuit board includes a plurality of fourth bonding portions bonded to each of the third bonding pad and the fifth pad through the plurality of the third bonding grooves.

33. The camera module of claim 26, comprising:
a plurality of pads disposed on the other end of the second board and one end of the second circuit board portion; and
a plurality of fifth bonding portions bonded to the plurality of pads disposed on the other end of the second board and one end of the second circuit board.

34. The camera module of claim 32, wherein a plurality of third pads is arranged vertically on one end of the first circuit board portion, a plurality of fourth pads is arranged vertically on the other end of the first board, a plurality of sixth pads is arranged vertically on one end of the second circuit board portion, and a plurality of seventh pads is arranged vertically on the other end of the second board.

35. The camera module of claim 26, comprising:
a housing covering the upper portions of the first and second lens assemblies, the first and second board portions and the outer side of the circuit board,
wherein the housing includes an open region with an open side.
